(19) United States
(12) Patent Application Publication
(10) Pub. No.: US 2026/0262406 A1
(43) Pub. Date: Sep. 3, 2026

(54) DISPLAY AND ELECTRONIC DEVICE

(71) Applicant: SONY SEMICONDUCTOR SOLUTIONS CORPORATION, KANAGAWA (JP)

(72) Inventors: AKIYOSHI AOYAGI, KANAGAWA (JP); TOMOAKI SUZUKI, KANAGAWA (JP); FUMITO KOMATSU, KANAGAWA (JP)

(21) Appl. No.: 19/164,598

(22) PCT Filed: Mar. 19, 2024
(86) PCT No.: PCT/JP2024/010678

§ 371 Date: Sep. 12, 2025

(30) Foreign Application Priority Data
Mar. 31, 2023 (JP) 2023-056978

(51) Int. Cl. H10K 59/131; H10K 59/12; H10K 59/122; H10K 77/10

(52) U.S. Cl. CPC H10K 59/1315; H10K 59/1201; H10K 59/122; H10K 77/10

(57) ABSTRACT

An object of the present disclosure is to provide a display and an electronic device capable of miniaturizing the size of an external electrode connecting a flexible printed circuit and a display panel, reducing the resistance of a connection portion between the flexible printed circuit and the display panel, and reducing thermal degradation of the display panel. A display includes: a display panel having a display region in which a light emitting element is disposed and an outer region formed outside the display region; and a flexible printed circuit having connection wiring electrically connected to the display panel, in which the display panel includes an external electrode provided in the outer region and electrically connectable to an outside, a bump electrode is provided on the first structure in a case where one of the external electrode and the connection wiring is a first structure and the other of the external electrode and the connection wiring with respect to the first structure is a second structure, and the bump electrode is metal-bonded to the second structure.

### TECHNICAL FIELD

The present disclosure relates to a display and an electronic device.

### BACKGROUND ART

As displays exemplified as display apparatuses or the like, there have been proposed displays including display panels having display regions and flexible printed circuits (FPCs) having connection wiring and electrically connectable to the outside. In such a display, Patent Document 1 discloses a technique in which an external electrode is provided outside a display region in a display panel, and the external electrode and connection wiring are electrically connected by an anisotropic conductive film (ACF) to connect the display panel and a flexible printed circuit.

### CITATION LIST

### Patent Document

Patent Document 1: Japanese Patent Application Laid-Open No. 2020-148847

### SUMMARY OF THE INVENTION

### Problems to be Solved by the Invention

Regarding the technology of connecting the display panel and the flexible printed circuit, there is room for further improvement in terms of miniaturization of the size of the external electrode connecting the flexible printed circuit and the display panel, reduction of the resistance of the connection portion between the flexible printed circuit and the display panel, and reduction of thermal degradation of the display panel.

The present disclosure has been made in view of the above-described points, and an object of the present disclosure is to provide a display and an electronic device capable of miniaturizing the size of an external electrode connecting a flexible printed circuit and a display panel, reducing the resistance of a connection portion between the flexible printed circuit and the display panel, and reducing thermal degradation of the display panel.

### Solutions to Problems

The present disclosure is, for example,
(1) a display panel having a display region in which a light emitting element is disposed and an outer region formed outside the display region; and
a flexible printed circuit having connection wiring electrically connected to the display panel, in which
the display panel includes an external electrode provided in the outer region and electrically connectable to an outside,
a bump electrode is provided on the first structure in a case where one of the external electrode and the connection wiring is a first structure and the other of the external electrode and the connection wiring with respect to the first structure is a second structure, and
the bump electrode is metal-bonded to the second structure.

The present disclosure may be (2) an electronic device including the display according to (1).

### BRIEF DESCRIPTION OF DRAWINGS

FIG. 1A is a perspective view for explaining one of examples of a display apparatus according to a first embodiment.

FIG. 1B is a plan view for explaining one example of the display apparatus according to the first embodiment.

FIG. 2 is a cross-sectional view for explaining a state of a cross-sectional view taken along line A-A in FIG. 1B.

FIG. 3 is a schematic exploded perspective view for explaining an example of the display apparatus according to the first embodiment.

FIG. 4 is a cross-sectional view for explaining an example of a display panel used in the display apparatus according to the first embodiment.

FIG. 5 is a cross-sectional view for explaining the method for manufacturing the display apparatus according to the first embodiment.

FIG. 6 is a cross-sectional view for explaining an example of the display apparatus according to the first embodiment.

FIG. 7 is a cross-sectional view for explaining an example of a display apparatus according to Modification 2 of the first embodiment.

FIG. 8 is a cross-sectional view for explaining an example of a display structure of the display apparatus according to the first embodiment.

FIG. 9 is a cross-sectional view for explaining an example of a flexible printed circuit of the display apparatus according to the first embodiment.

FIG. 10 is a cross-sectional view for explaining an example of a display apparatus according to Modification 1 of the first embodiment.

FIG. 11A is a cross-sectional view for explaining an example of a display panel of the display apparatus according to Modification 1 of the first embodiment. FIG. 11B is a cross-sectional view for explaining the method for manufacturing the display apparatus according to Modification 1 of the first embodiment.

FIGS. 12A, 12B, and 12C are plan views for explaining an example of the layout of external electrodes provided in the display apparatus according to the first embodiment.

FIG. 13 is a cross-sectional view for explaining an example of a display apparatus according to a second embodiment.

FIG. 14A is a cross-sectional view for explaining an example of a display panel of the display apparatus according to the second embodiment. FIG. 14B is a cross-sectional view for explaining the method for manufacturing the display apparatus according to the second embodiment.

FIG. 15 is a cross-sectional view for explaining an example of a display apparatus according to a third embodiment.

FIG. 16A is a cross-sectional view for explaining an example of a display panel of the display apparatus according to the third embodiment. FIG. 16B is a cross-sectional view for explaining the method for manufacturing the display apparatus according to the third embodiment.

FIG. 17 is a cross-sectional view for explaining an example of a display apparatus according to a fourth embodiment.

FIG. 18 is a cross-sectional view for explaining an example of the display apparatus according to the fourth embodiment.

FIG. 19 is a cross-sectional view for explaining an example of a display apparatus according to a fifth embodiment.

FIG. 20 is a cross-sectional view for explaining an example of a display apparatus in which the fourth embodiment and the fifth embodiment are combined.

FIG. 21A is a cross-sectional view for explaining an example of the display apparatus according to the fourth embodiment. FIG. 21B is a cross-sectional view for explaining an example of the display apparatus according to the fifth embodiment.

FIG. 22A is a cross-sectional view for explaining an example of the display apparatus according to the fourth embodiment. FIG. 22B is a cross-sectional view for explaining an example of the display apparatus according to the fifth embodiment.

FIG. 23A is a cross-sectional view for explaining an example of the display apparatus according to the fourth embodiment. FIG. 23B is a cross-sectional view for explaining an example of the display apparatus according to the fifth embodiment.

FIG. 24 is a cross-sectional view for explaining an example of a display apparatus according to Modification 1 of the fifth embodiment.

FIG. 25 is a cross-sectional view for explaining an example of a display apparatus according to Modification 2 of the fifth embodiment.

FIG. 26A is a cross-sectional view for explaining an example of a display apparatus according to Modification 3 of the fifth embodiment. FIG. 26B is a cross-sectional view for explaining a state of a cross-sectional view taken along line B-B in FIG. 26A.

FIGS. 27A, 27B, and 27C are cross-sectional views for explaining an example of the method for manufacturing the display apparatus according to the fifth embodiment.

FIGS. 28A and 28B are cross-sectional views for explaining an example of the method for manufacturing the display apparatus according to the fifth embodiment.

FIG. 29 is a cross-sectional view for explaining an example of a display apparatus according to a first example of a sixth embodiment.

FIGS. 30A and 30B are perspective views for explaining an example of the method for manufacturing the display apparatus according to the sixth embodiment.

FIGS. 31A and 31B are perspective views for explaining an example of the method for manufacturing the display apparatus according to the sixth embodiment.

FIGS. 32A and 32B are cross-sectional views for explaining an example of a display apparatus according to a second example of the sixth embodiment.

FIG. 33 is a cross-sectional view for explaining a state of a cross-sectional view taken along line C-C in FIG. 32A.

FIG. 34 is a cross-sectional view for explaining an example of a display apparatus according to a seventh embodiment.

FIG. 35 is a cross-sectional view for explaining an example of a flexible printed circuit of the display apparatus according to the seventh embodiment.

FIG. 36A is a perspective view for explaining an example of the method for manufacturing the display apparatus according to the seventh embodiment. FIG. 36B is a perspective view for explaining an example of the method for manufacturing the display apparatus according to the seventh embodiment.

FIG. 37 is a cross-sectional view for explaining an example of the method for manufacturing the display apparatus according to the seventh embodiment.

FIG. 38 is a cross-sectional view for explaining an example of a bump electrode of the display apparatus according to the seventh embodiment.

FIG. 39 is a cross-sectional view for explaining an example of the display apparatus according to the seventh embodiment.

FIGS. 40A and 40B are cross-sectional views for explaining an example of a flexible printed circuit of the display apparatus according to the seventh embodiment.

FIGS. 41A and 41B are diagrams for explaining an application example of the display apparatus.

FIG. 42 is a diagram for explaining an application example of the display apparatus.

FIG. 43 is a diagram for explaining an application example of the display apparatus.

FIG. 44 is a diagram for explaining an application example of the display apparatus.

FIG. 45 is a diagram for explaining an application example of the display apparatus.

FIGS. 46A and 46B are diagrams for explaining an application example of the display apparatus.

### MODE FOR CARRYING OUT THE INVENTION

Hereinafter, embodiments and the like according to the present disclosure will be described with reference to the drawings. Note that the description will be given in the following order. In the present specification and the drawings, components having substantially the same functional configuration are denoted by the same reference signs, and redundant description will be omitted.

Examples of the display according to one embodiment of the present disclosure include various lighting apparatuses (neon signs of advertisements and the like) and display apparatuses.

In the following first to seventh embodiments and application examples, a case where the display is a display apparatus (an application example relates to an object to which the display apparatus can be applied) will be described as an example. The display according to the present disclosure is not limited to each of the examples exemplified above, but in a case where the display is a display apparatus, the effectiveness can be further enhanced.

The description will be given in the following order.
1. First Embodiment
2. Second Embodiment
3. Third Embodiment
4. Fourth Embodiment
5. Fifth Embodiment
6. Sixth Embodiment
7. Seventh Embodiment
8. Application Example

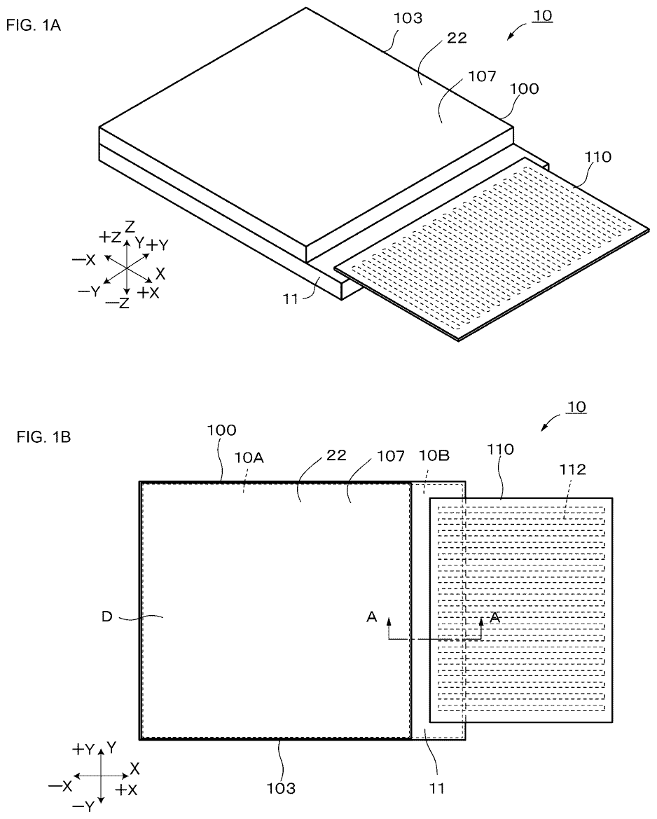

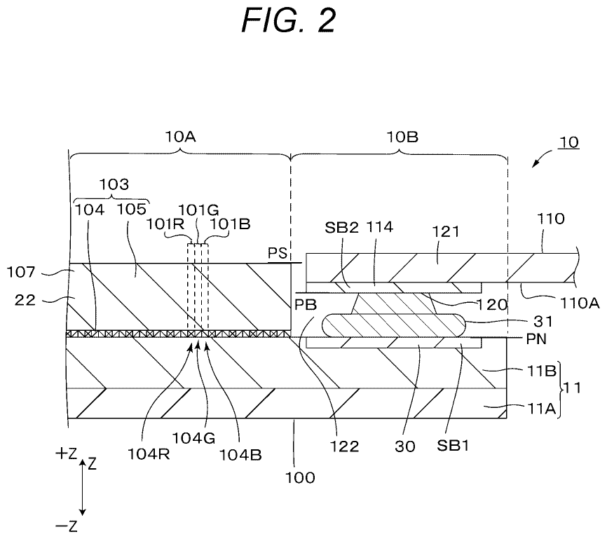

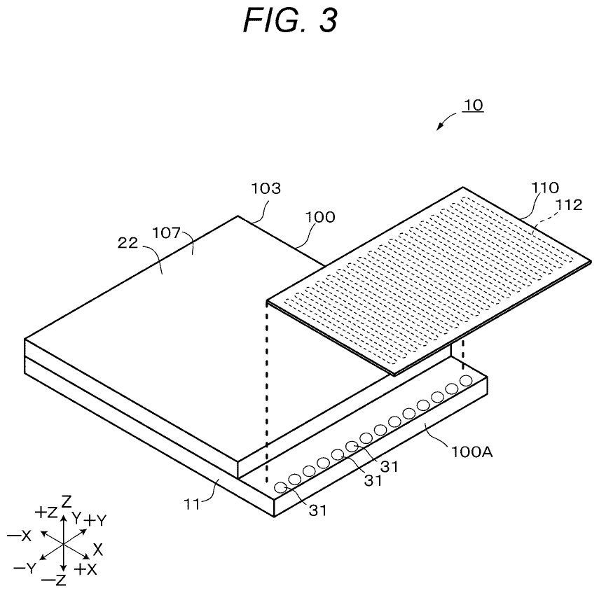

The following description is a preferred specific example of the present disclosure, and the content of the present disclosure is not limited to these embodiments and the like. In addition, in the following description, directions such as front and back, left and right, and up and down are indicated in consideration of convenience of description, but the content of the present disclosure is not limited to these directions. In the examples of FIGS. 1A, 1B, and 2, it is assumed that a Z-axis direction is a vertical direction (upper side is in the +Z direction and the lower side is in the −Z direction), an X-axis direction is a front-rear direction (front side is in the +X direction and rear side is in the −X direction), and a Y-axis direction is a left-right direction (right side is in the −Y direction and left side is in the +Y direction), and the description will be made on the basis of this. It similarly applies to FIGS. 3 to 40. The relative magnitude ratios of the sizes and thicknesses of the layers illustrated in each drawing of FIG. 1A and the like are described for convenience, and do not limit actual magnitude ratios. It similarly applies to the drawings of FIGS. 1B and 2 to 40 as to the definition and the magnitude ratio regarding these directions.

### 1 First Embodiment

### 1-1 Configuration

Examples of the display apparatus as an example of the display according to one embodiment of the present disclosure include an apparatus (organic EL display apparatus) having an organic electroluminescence (EL) element, an apparatus having a light emitting diode (LED), and the like. In the description of the first embodiment, a case where the display apparatus is an organic EL display apparatus (hereinafter, simply referred to as a “display apparatus 10”) as illustrated in FIGS. 1A, 1B, or the like will be described as an example. Note that it similarly applies to the second to seventh embodiments described later. FIG. 1A is a perspective view illustrating an example of display apparatus 10. FIG. 1B is a plan view for explaining the display apparatus 10 in FIG. 1A. A display apparatus in a case where a display apparatus as an example of a display according to one embodiment of the present disclosure is an apparatus having an LED can be realized by adopting an LED as a light emitting element instead of adopting a fixed-term EL element as a light emitting element to be described later in any of the first to seventh embodiments.

As illustrated in FIG. 1A, the display apparatus 10 includes a display panel 100 and a flexible printed circuit 110. In the display apparatus 10, the flexible printed circuit 110 and the display panel 100 are electrically connected.

### Display Panel

The display panel 100 has a display region 10A and an outer region 10B formed outside the display region 10A on the display surface D side. As illustrated in FIG. 2, the display panel 100 includes a substrate 11A, a light emitting element 104, and a display structure 103 including a covering structure 105 that covers the light emitting element 104. The display structure 103 is a structure that emits light generated by the plurality of light emitting elements 104. The display structure 103 is formed in the display region 10A of the display panel 100.

### Display Region and Outer Region

The display region 10A is a region determined as a region where the light emitting element 104 is disposed. The outer region 10B is defined as a region outside the outer peripheral edge of the display region 10A. In the example of FIG. 1B, the display region 10A is formed as a rectangular region. Furthermore, in this example, the display region 10A also corresponds to a formation region of the display structure 103. A region defined as a rectangular region outside the display region 10A is an outer region 10B. In FIG. 1B, the outer region 10B is in contact with a boundary of one side of the display region 10A, and a region outside the boundary (a direction away from the display region 10A) is the outer region 10B. That the outer region 10B is in contact with the boundary of the display region 10A indicates that the position of the outer edge of the display region 10A is the position of the inner end of the outer region 10B. Note that display surface D illustrated in FIG. 1B indicates a surface (light emitting surface) of the display panel 100 from which light generated from the light emitting element 104 is extracted to the outside.

Hereinafter, a case where the display apparatus 10 includes the display panel 100 displayed by the top emission type will be described as an example. The top emission type indicates a type in which the light emitting element 104 is disposed on the light emitting surface side of the substrate 11A. Therefore, in the display apparatus 10, the substrate 11A is located on the back surface side of the display apparatus 10, and the direction (+Z direction) from the substrate 11A toward the light emitting element 104 to be described later is the front surface side (upper surface side) direction of the display apparatus 10. In the display apparatus 10, the light generated from the light emitting element 104 is directed in the +Z direction and emitted to the outside. In the following description of the present specification, in each layer constituting the display apparatus 10, a surface on the display surface D side in the display region 10A of the display apparatus 10 is referred to as a first surface (upper surface), and a surface on the back surface side of the display apparatus 10 is referred to as a second surface (lower surface). Note that this does not prohibit the case where the display apparatus 10 according to the present disclosure is of the bottom emission type. The display apparatus 10 is also applicable to a bottom emission type. In the bottom emission type, light generated from the light emitting element 104 is directed in the −Z direction and emitted to the outside.

### Substrate

The substrate 11A may be constituted by, for example, glass or resin having low permeability for moisture and oxygen, or may be constituted by a semiconductor in which a transistor or the like is easily formed. Specifically, the substrate 11A may be a glass substrate, a silicon substrate, a semiconductor substrate, a resin substrate, or the like.

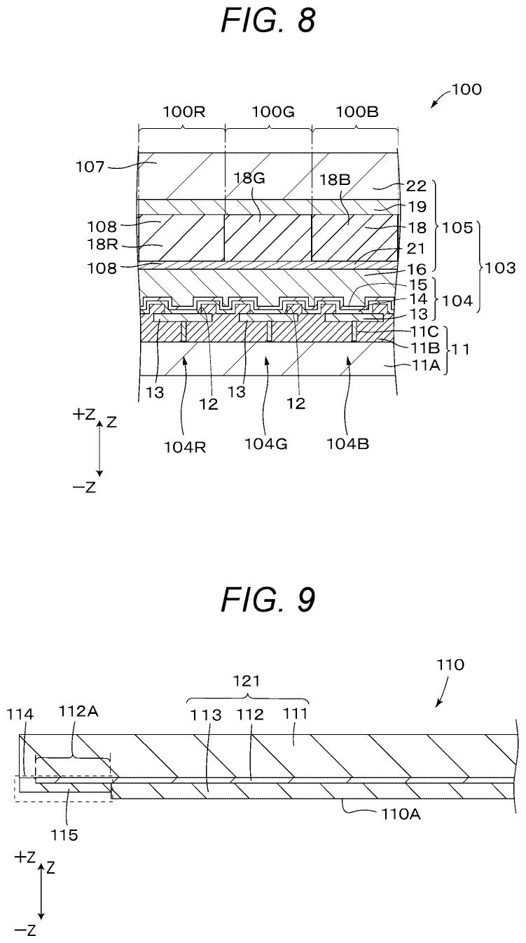

As illustrated in FIG. 2, an inorganic insulating layer 11B is provided on the upper surface side of the substrate 11A. FIG. 2 is a cross-sectional view schematically illustrating a state of a longitudinal cross section taken along line A-A in FIG. 1B. Various circuits for driving the plurality of light emitting elements 104 may be provided on the first surface of the substrate 11A or in the inorganic insulating layer 11B. Examples of the various circuits include a driving circuit that controls driving of the light emitting element 104 and a power supply circuit (none of which are illustrated) that supplies power to the plurality of light emitting elements 104. The various circuits are restricted from being exposed to the outside by the inorganic insulating layer 11B. In addition, on the upper side of the substrate 11A, wiring for connecting the light emitting element 104 and a circuit or the like provided on the substrate 11A to the first electrode 13 or the like is provided. Examples of the wiring include a plurality of contact plugs 11C (for example, described later in FIG. 8). Note that, in the present specification, a structure in which the inorganic insulating layer 11B and various circuits (for example, including wiring such as the contact plug 11C) are formed on the substrate 11A is referred to as a drive substrate 11.

### Inorganic Insulating Layer

The inorganic insulating layer 11B is constituted by, for example, an organic material or an inorganic material. The organic material includes, for example, at least one of polyimide or acrylic resin. The inorganic material includes, for example, at least one of silicon oxide, silicon nitride, silicon oxynitride, or aluminum oxide.

### External Electrode

In the display panel 100, the external electrode 30 is provided on the first surface side of the substrate 11A (first surface side of the drive substrate 11) in the outer region 10B. As the external electrode 30, an electrode pad that functions as a connection terminal for electrically connecting the display panel 100 and the flexible printed circuit 110 can be suitably employed. Examples of the terminal that electrically connects the display panel 100 and the flexible printed circuit 110 include a terminal that functions as a terminal that electrically connects the light emitting element 104 and the like to the outside. Although not illustrated, the external electrode 30 may be electrically connected to various circuits and the like (for example, a drive circuit, a power supply circuit, and the like) provided on the drive substrate 11 described above by wiring or the like.

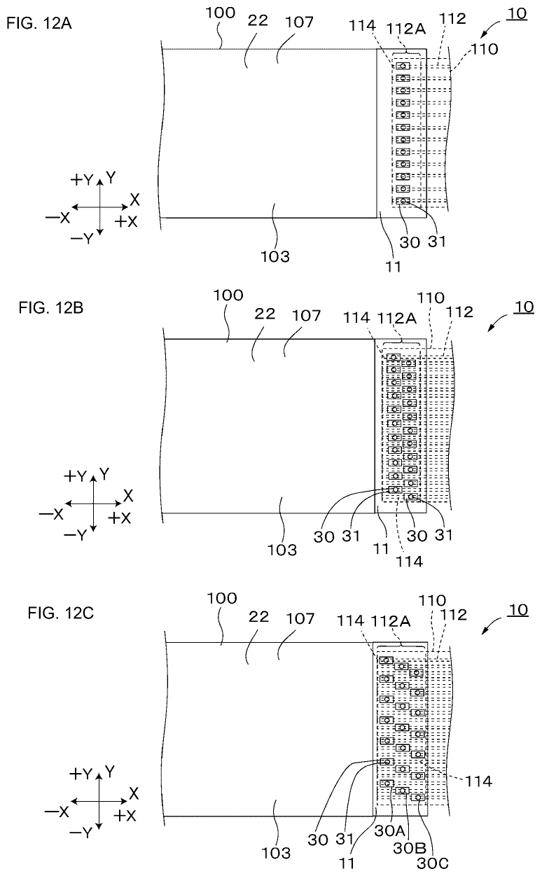

In the examples of FIGS. 1 and 2, the external electrode 30 is formed on the inorganic insulating layer 11B and exposed to the first surface side of the inorganic insulating layer 11B. Note that the layout of the external electrodes 30 is not particularly limited as long as each external electrode corresponds to a connection wiring 114 of the flexible printed circuit 110 to be described later. For example, in the example of FIG. 12A, a plurality of external electrodes is provided in the outer region so as to be aligned in a line along the direction in which one side of the display region 10A extends. However, this is an example, and the layout of the plurality of external electrodes is not limited thereto. FIG. 12A is a diagram for explaining an example of a layout of external electrodes 30 of the display apparatus 10 illustrated in FIGS. 1A and 1B. Note that, in FIG. 12A, the flexible printed circuit 110 and the wiring 112 (and the connection wiring 114) in a case where the flexible printed circuit 110 is disposed are indicated by broken lines. It similarly applies to FIGS. 12B and 12C.

The material of the external electrode 30 is not particularly limited as long as it has conductivity, and examples thereof include aluminum, copper, and ITO. The external electrode 30 is preferably formed in a pattern in accordance with the formation of the first electrode 13 or the formation of the various circuits and wirings while using the same material as, for example, the first electrode 13 described later and the various circuits and wirings described above.

It is sufficient that the size (size of exposed portion in state in which the flexible printed circuit 110 is not connected to the display panel 100) of the exposed portion of the external electrode 30 exposed from the inorganic insulating layer 11B is set to such a size that the bump electrode 31 can be formed in a state where the electrical connection between the external electrode 30 and the bump electrode 31 is secured. From this viewpoint, the size of the exposed portion of the external electrode 30 is preferably ensured to be about the size of the bump electrode 31.

### Bump Electrode

In the display apparatus 10, in a case where one of the external electrode 30 and the connection wiring 114 is a first structure SB1 and the other of the external electrode 30 and the connection wiring 114 different from the first structure is a second structure SB2, the bump electrode 31 is provided on the first structure SB1, and the bump electrode 31 is metal-bonded to the second structure SB2. Both the first structure SB1 and the second structure SB2 are conductive structures and are formed so as to be able to function as electrical terminals. In the display apparatus 10 described as an example of the first embodiment, the external electrode 30 in the outer region 10B is the first structure SB1, and the connection wiring 114 of the flexible printed circuit 110 is the second structure SB2. Then, the external electrode 30 is provided with the bump electrode 31. In the example of FIG. 2, the bump electrode 31 is provided on the surface of the external electrode 30 in the outer region 10B. The material of the bump electrode 31 is a metal material. The material of the bump electrode 31 is preferably one having low electric resistance among metal materials, and specifically preferably at least one selected from the group consisting of gold, copper, silver, and aluminum. One bump electrode 31 may be provided for one external electrode 30, or a plurality of bump electrodes may be provided.

The bump electrode 31 is a stud bump in the example of FIG. 2. The stud bump can be formed on the external electrode 30 by using, for example, a metal wire such as a gold wire corresponding to the material of the bump electrode 31 and a wire bonding technique. The size of the bump electrode 31 is not particularly limited, but can be determined to be about the size of a stud bump. Note that, specifically, the size of the bump electrode 31 can be, for example, 100 μm or less in diameter in a plan view of the external electrode 30 (in a plan view of the display apparatus 10). Note that the plan view of the external electrode 30 (plan view of the display apparatus 10) corresponds to a state recognized in a case where the Z-axis direction is set as the line-of-sight direction in the examples of FIGS. 1B and 2. Although the case where bump electrode 31 is a stud bump has been described with reference to the example of FIG. 2, the bump electrode 31 may be formed by a plating method or may be formed by solder as described later. Further, the bump electrode 31 may be formed by applying a vapor deposition film forming method or may be formed by applying a sputtering film forming method.

### Flexible Printed Circuit

The flexible printed circuit 110 includes a so-called flexible printed circuit board (Flexible Printed Circuit; FPC). As illustrated in FIGS. 2, 3, and 9, the flexible printed circuit 110 includes a base material layer 111, wiring 112 formed on the base material layer 111, and a cover layer 113 covering the wiring 112. In the flexible printed circuit 110, a portion (wiring portion 112A) of the wiring 112 that is not covered with the cover layer 113 is formed on one end side. The wiring portion 112A of the wiring 112 in the flexible printed circuit 110 can function as a terminal connected to the bump electrode 31. The wiring portion 112A may be exposed to the outside as it is, but as illustrated in the example of FIG. 9 and the like, it is preferable to form a metal coating layer 115 which is a metal layer coating the wiring portion 112A. The material of the metal coating layer 115 coating the wiring portion 112A is not particularly limited, but is preferably gold or a laminated film of nickel and gold from the viewpoint of conductivity. The metal coating layer 115 is preferably formed in an individually separated state with respect to each wiring portion 112A, and the metal coating layer 115 is preferably formed in a layout corresponding to the layout of the wiring portion 112A. Note that, in the flexible printed circuit 110, a portion that includes wiring portion 112A and is a connection terminal electrically connected to the display panel 100 is referred to as connection wiring 114. In the examples of FIGS. 2 and 9 and the like, a portion where the wiring portion 112A and the metal coating layer 115 are laminated (laminated structure portion) is defined as the connection wiring 114. In addition, the flexible printed circuit 110 preferably has a connection terminal (not illustrated) formed as a terminal to be connected to the outside on the other end side which is the opposite end side to the formation end side of the connection wiring 114. The connection terminal and the connection wiring 114 become a first terminal and a second terminal as two terminals formed on the flexible printed circuit 110, respectively. In a case where the first terminal is connected to the external apparatus and the second terminal is connected to the display panel 100, the flexible printed circuit 110 relays the electrical connection between the external apparatus and the display panel 100. Note that FIG. 3 is an exploded perspective view for explaining an example of the display apparatus 10 according to the first embodiment, and FIG. 9 is a cross-sectional view for explaining an example of the flexible printed circuit 110. In FIG. 3, the description of the external electrode 30 is omitted for convenience of description.

In the first embodiment, the connection wiring 114 is the second structure SB2 described above. The layout of the connection wiring 114 is a layout corresponding to the layout of the bump electrode 31, and in the example of FIGS. 1A, 1B, 2, 3, and the like, the layout (layout of the first terminal) of the connection wiring 114 is determined such that one connection wiring 114 corresponds to one bump electrode 31. In the example of FIG. 3 and the like, the plurality of connection wirings 114 is arranged in a line in the drawing, but this does not limit the arrangement of the connection wirings 114. The arrangement of the connection wirings 114 may be determined according to various conditions such as the wiring state of the wiring 112 and the layout of the external electrode 30, the bump electrode 31, and the like. Note that, in FIG. 2, the connection wiring 114 is described as a structure having a thickness enough to protrude downward, but the structure of the connection wiring 114 is not limited.

### Bonding of Display Panel and Flexible Printed Circuit

In the display apparatus 10, the flexible printed circuit 110 is disposed on the display panel 100 with the connection wiring 114 facing the first surface side of the outer region 10B such that the connection wiring 114 is positioned on the outer region 10B. In addition, the individual connection wirings 114 of the flexible printed circuit 110 and the individual external electrodes 30 face each other, and the bump electrode 31 is disposed between the connection wirings 114 and the external electrodes 30. In addition, in the display apparatus 10, the bump electrode 31 provided on the external electrode 30 of the display panel 100 and the connection wiring 114 of the flexible printed circuit 110 are metal-bonded. The metal bonding indicates that the metals are directly bonded to each other, and indicates that the metal forming the bump electrode 31 and the metal forming the connection wiring 114 are directly bonded to each other. The flexible printed circuit 110 and the display panel 100 (for example, the light emitting element 104, various circuits, and the like) are electrically connected to each other by such metal bonding. Note that, in the first embodiment, a portion where the bump electrode 31 of the display panel 100 and the connection wiring 114 of the flexible printed circuit 110 are metal-bonded to each other (a portion where the bump electrode 31 and the second structure SB2 are metal-bonded to each other) is referred to as a metal bonding portion 120. Also in the second to sixth embodiments, the metal bonding portion 120 is a portion where the bump electrode 31 of the display panel 100 and the connection wiring 114 of the flexible printed circuit 110 are metal-bonded to each other. Note that, from the viewpoint of forming the metal bonding portion 120 more closely, the metal of the outermost surface of the connection wiring 114 and the metal of the outermost surface of the bump electrode 31 may be the same kind. Specifically, the outermost surfaces of the metal coating layer 115 and the bump electrode 31 of the connection wiring 114 may both be constituted by gold.

### Ultrasonic Bonding

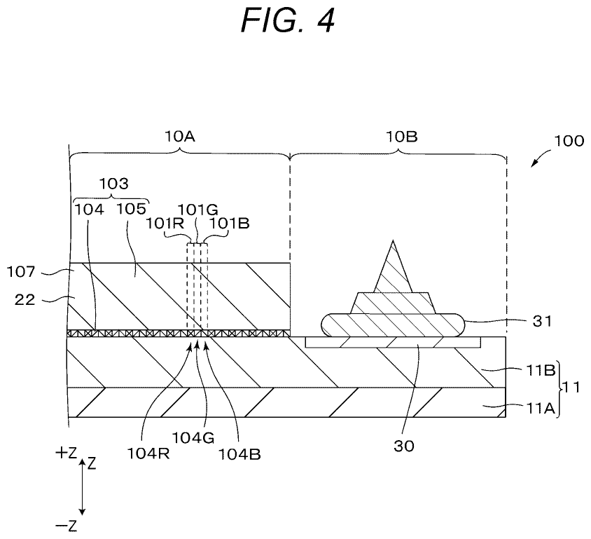

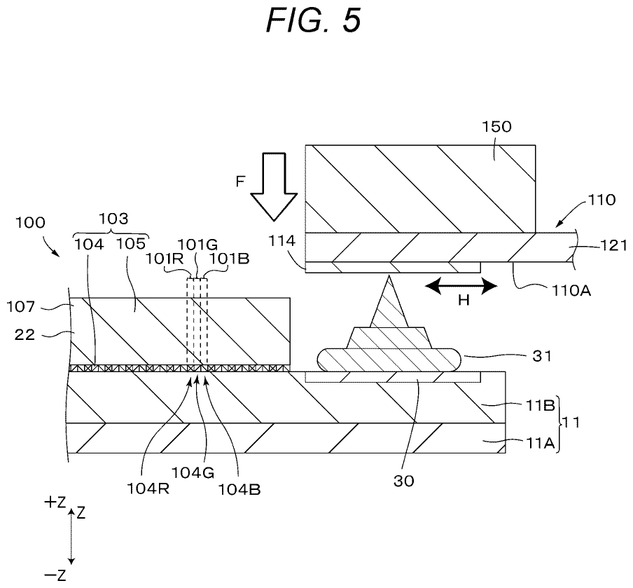

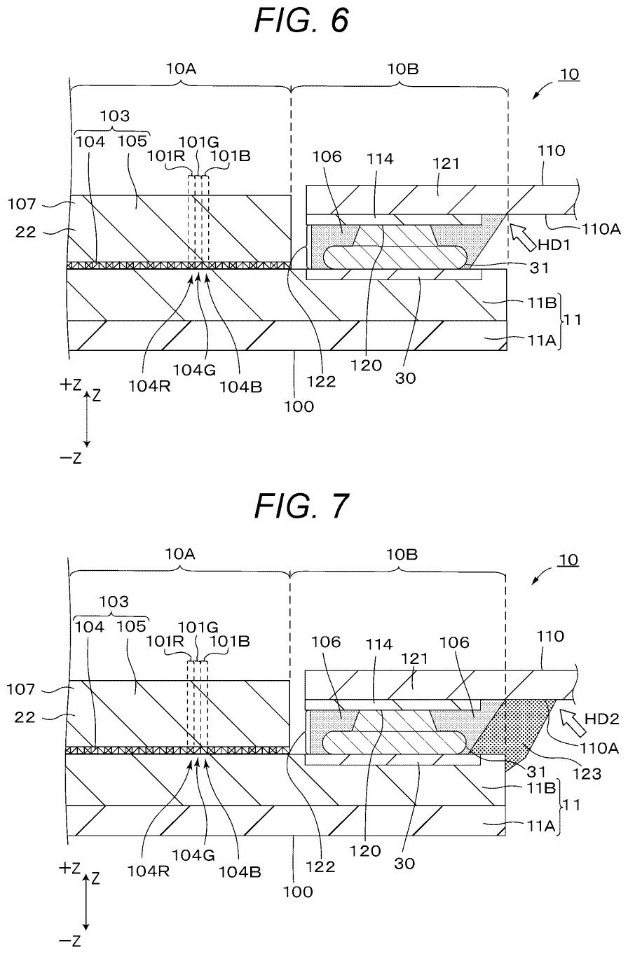

The metal bonding portion 120 between the bump electrode 31 and the connection wiring 114 of the flexible printed circuit 110 can be formed by, for example, ultrasonic bonding. The ultrasonic bonding is not particularly limited as long as it is a method for realizing metal bonding by ultrasonic waves, and can be performed, for example, as follows. As illustrated in FIG. 4, the display panel 100 in which the bump electrode 31 is formed on the first surface of the external electrode 30 is prepared. As illustrated in FIG. 5, the flexible printed circuit 110 is attracted to and held by a head 150, the surface of the flexible printed circuit 110 on which the connection wiring 114 is formed is disposed so as to be oriented toward a predetermined position in the outer region 10B of the display panel 100, and the external electrode 30 of the display panel 100 and the connection wiring 114 of the flexible printed circuit 110 are aligned (alignment). At this time, alignment is performed such that the bump electrode 31 is positioned between the external electrode 30 and the connection wiring 114. Then, the head 150 pressurizes the opposing portion between the connection wiring 114 and the bump electrode 31 in the arrow F direction and applies an ultrasonic wave toward the opposing portion. The ultrasonic wave preferably generates vibration in a plane direction of the flexible printed circuit 110 (vibration in an arrow H direction) as generally illustrated in FIG. 5. At this time, the bump electrode 31 and the connection wiring 114 are bonded by solid-phase diffusion. In the example of FIG. 5, the bump electrode 31 and the connection wiring 114 are constituted by metal, and a bonding portion between the bump electrode 31 and the connection wiring 114 is formed as a metal bonding portion 120. Note that, in FIG. 5, for convenience of explanation, the base material layer 111, the wiring 112, the cover layer 113, and the metal coating layer 115 are not distinguished. In FIG. 5, reference sign 121 denotes a circuit forming body including the base material layer 111, the wiring 112, the cover layer 113, and the metal coating layer 115. In FIG. 5, the connection wiring 114 is clearly illustrated separately from the circuit forming body 121, and the flexible printed circuit 110 is described as a structure having the circuit forming body 121 and the connection wiring 114. It similarly applies to FIGS. 6, 7, and the like.

With respect to the condition of ultrasonic bonding, it is preferable that the pressurization condition by the head 150 is within a range of about 15 gf or more and 80 gf or less with respect to one bump electrode 31. Furthermore, as conditions of the ultrasonic wave to be applied, it is preferable that the amplitude is within a range of 1 μm or more and 8 μm or less and the application time is within a range of 0.05 seconds or more and 2 seconds or less, and the vibration direction in the ultrasonic bonding is preferably an extending direction (for example, in FIG. 5, in a case where the direction along the arrow H is the longitudinal direction of the wiring, the direction along the arrow H) of the wiring of the flexible printed circuit. In a case where such a pressurization condition and a condition of an ultrasonic wave to be applied are satisfied, it is easy to form a state in which the bump electrode 31 and the connection wiring 114 of the flexible printed circuit 110 are metal-bonded more closely.

### Relationship Between Position of External Electrode and Outermost Surface of Display Structure

With respect to the position of the external electrode 30, it is preferable that a position PS of the outermost surface of the covering structure 105 (which is also the position of the upper surface or the position of the exposed surface) to be described later is above a position PN of the upper surface of the external electrode 30 (the position of the first surface) (the position PN of the upper surface of the external electrode 30 is below the position PS of the outermost surface of the covering structure). Note that, in the example of FIG. 2, the position PS of the outermost surface of the covering structure 105 is the position of the first surface of the counter substrate 22, and the position of the first surface of the counter substrate 22 exists above the external electrode 30.

Since the display apparatus 10 has a configuration in which the upper surface of the external electrode 30 is positioned below the outermost surface of the covering structure 105, even in a case where the display apparatus 10 has a configuration (sealing structure 106) in which the gap 122 between the flexible printed circuit 110 and the display panel 100 is filled with an underfill material to be described later, occurrence of a state in which the underfill material flows into the display region 10A of the display panel 100 can be suppressed.

### Relationship Between Position of Flexible Printed Circuit and Upper End Position of Display Structure

In the state where the metal bonding portion 120 is formed, it is preferable that the position PB of the lower surface 110A of the flexible printed circuit 110 is located below the upper end position of the display structure 103 (the upper end position (position PS) of the covering structure 105). The lower surface 110A corresponds to a surface of the flexible printed circuit 110 facing the outer region 10B of the display panel 100. The position PB of the lower surface 110A indicates a portion corresponding to the bonding surface between the connection wiring 114 and the bump electrode 31 in the portion where the metal bonding portion 120 is formed. Note that, in FIG. 2, the position PB is described to be larger and lower than the lower surface 110A, but for convenience of description, the connection wiring 114 is illustrated with a thickness.

Since the display apparatus 10 has the position PB of the lower surface 110A of the flexible printed circuit below the position PS of the outermost surface of the covering structure 105, similarly to the case where the positional relationship between the outermost surface of the covering structure 105 and the upper surface of the external electrode 30 is described, even in a case where the display apparatus 10 has a configuration in which an underfill material described later is filled in a gap between the flexible printed circuit 110 and the display panel 100 so as to cover the metal bonding portion 120, occurrence of a state in which the underfill material flows into the display region 10A of the display panel 100 can be suppressed.

### Sealing Structure

In FIG. 2, the gap 122 between the flexible printed circuit 110 and the display panel 100 is illustrated as a void portion, but as illustrated in FIG. 6, the gap 122 is preferably filled with an underfill material as a resin so as to cover the metal bonding portion 120. FIG. 6 is a cross-sectional view illustrating an example in a case where the display apparatus 10 according to the first embodiment has the sealing structure 106. As also illustrated in FIG. 6, the gap 122 indicates a space sandwiched between the surface of the flexible printed circuit 110 and the surface of display panel 100 (the surface of the outer region 10B) facing each other. It similarly applies to the second embodiment and the third embodiment described later in that it is preferable to fill the gap 122 with the underfill material.

The portion constituted by the underfill material that covers the metal bonding portion 120 is a portion that seals the metal bonding portion 120 from the outside, and is hereinafter referred to as a sealing structure 106. In plan view of the display apparatus 10, the region where the sealing structure 106 is formed is not particularly limited as long as it is a region that covers the metal bonding portion 120 in the region where the flexible printed circuit 110 and the display panel 100 face each other, and may be the entire region where the flexible printed circuit 110 and the display panel 100 face each other (the entire formation region of the gap 122), or may be formed up to the region outside the gap 122. In the case that the gap 122 is formed to the outer region, the gap may be formed from the region where the flexible printed circuit 110 and the display panel 100 face each other to the slightly outer region (the further outer side of the outer region 10B) and/or the inner region (the region close to the display region 10A). For example, in a case where the underfill material is injected so as to overflow from the space of the gap 122 toward the gap 122 between the flexible printed circuit 110 and the display panel 100, the underfill material may overflow outward or inward from the space of the gap 122 between the flexible printed circuit 110 and the display panel 100. However, in a case where the underfill material overflows inward from the space of the gap 122 between the flexible printed circuit 110 and the display panel 100, it is preferable that the underfill material remains in a region (inside the outer region 10B) to the outside of the display region 10A.

Examples of the underfill material include a resin material that can be cured even under relatively low temperature conditions, and an ultraviolet curable resin. Examples of the resin material capable of being cured even under relatively low temperature conditions include an epoxy resin capable of being cured at about 90° C., and specifically, trade name “9000AA” manufactured by Henkel Corporation can be exemplified. Specific examples of the ultraviolet curable resin include “SUV-511Y” (trade name) manufactured by Sanyu Rec Co., Ltd.

### Filling of Underfill Material

The filling of the underfill material can be performed, for example, as follows. A needle is disposed at a position of an outer end of the display panel 100, and an underfill material is extruded from a tip of the needle toward the gap 122, for example, in a direction of an arrow HD1 in FIG. 6, and attached to the flexible printed circuit 110. As a result, the underfill material can be drawn into the gap 122 between the flexible printed circuit 110 and the display panel 100 using the capillary phenomenon, and a state in which the underfill material is filled in the gap 122 between the flexible printed circuit 110 and the display panel 100 can be formed. Then, the injected underfill material is cured to form the sealing structure 106. The curing of the underfill material can be achieved by applying heating, ultraviolet irradiation, or the like depending on the properties of the underfill material used. Note that, in the case of performing the method of filling the underfill material using the capillary phenomenon as described above, the temperature of the stage on which the display panel 100 and the flexible printed circuit 110 are disposed is preferably adjusted to a range of about 40° C. to 80° C. when the underfill material is filled. Since the temperature of the stage is adjusted in this manner, the viscosity of the underfill material can be appropriately reduced, and the underfill material can be more efficiently injected into the gap 122 between the flexible printed circuit 110 and the display panel 100. In addition, when the underfill material is attached to the flexible printed circuit 110, the underfill material is preferably linearly attached along the outer end of the display panel 100 at the position of the outer end of the display panel 100. Note that the method of filling the underfill material using the capillary phenomenon described above is an example, and the method of filling the underfill material is not limited thereto.

### Structure Formed in Display Region

In the example of the display apparatus 10 illustrated in FIG. 2 and the like, the subpixel 101 is formed in the display region 10A of the display panel, and the display structure 103 has a structure corresponding to the layout of the subpixel 101. An example of the subpixel 101 and the display structure 103 will be described next with reference to FIGS. 2, 8, and the like. Note that FIG. 8 is a cross-sectional view for explaining an example of the light emitting element 104.

### Type of Subpixel

In the example of FIG. 2 and the like, three colors of red, green, and blue are determined as a plurality of color types corresponding to the emission color of the display panel of the display apparatus 10, and three types of the subpixel 101R, the subpixel 101G, and the subpixel 101B are provided as the subpixels. The subpixel 101R, the subpixel 101G, and the subpixel 101B are a red subpixel, a green subpixel, and a blue subpixel, respectively, and display red, green, and blue, respectively. However, the example of FIG. 2 is an example, and the display apparatus 10 is not limited to a case of including a plurality of subpixels corresponding to three color types. Furthermore, the wavelengths of light corresponding to the respective color types of red, green, and blue can be determined as, for example, wavelengths in the range of 610 nm to 650 nm (red wavelength band), the range of 510 nm to 590 nm (green wavelength band), and the range of 440 nm to 480 nm (blue wavelength band), respectively. Note that the number of color types of the subpixels is not limited to the three colors illustrated here, and may be two colors, four colors, or the like. Furthermore, the color type of the subpixel is not limited to red, green, and blue, and may be yellow, white, or the like.

Furthermore, the layout of the subpixels 101B, 101R, and 101G in the display panel is not particularly limited, and for example, in a predetermined region constituting the display surface D, the subpixels 101B, 101R, and 101G constituting one pixel may be arranged in a stripe shape, and each pixel may be two-dimensionally provided.

In the description of the present specification, in a case where the types of the subpixels 101R, 101G, and 101B are not particularly distinguished, the subpixels 101R, 101G, and 101B are collectively referred to as the subpixels 101.

### Drive of Subpixel

The display panel of the display apparatus 10 generally includes a control circuit (not illustrated), an H driver, and a V driver (not illustrated), and the control circuit controls driving of the H driver and the V driver. The H driver and the V driver control driving of the subpixels 101 in units of columns and rows, respectively, in a case where a two-dimensional matrix is allocated to each subpixel 101.

### Display Structure of Display Panel

The display structure 103 formed on the display panel 100 includes the light emitting element 104 and the covering structure 105 covering the light emitting element 104. In addition, although not illustrated, in this example, the light emitting element 104 is electrically connected to various circuits, and is controlled by an H driver, a V driver, or the like. The circuit electrically connected to the light emitting element 104 is electrically connected to the external electrode 30 described above.

In the example of FIG. 2, the display structure 103 has a structure in which the inorganic insulating layer 11B and a light emitting element 104 are formed on the substrate 11A. Here, as will be described later with reference to FIG. 8, the light emitting element 104 has a structure in which a first electrode 13, an organic layer 14, and a second electrode 15 are laminated in this order. FIG. 8 is a cross-sectional view for explaining an example of the display structure.

### Light Emitting Element

In the display panel 100, a plurality of light emitting elements 104 is provided on the first surface of the inorganic insulating layer 11B. In the example of FIG. 2 and the like, the light emitting element 104 is an organic electroluminescent element (organic EL element). When the light generated from the subpixel 101 corresponds to the color type of the subpixel 101, the emission color of the light emitting element 104 formed in the subpixel 101 is not particularly limited, but for example, a light emitting element that sets the color corresponding to the color type of the subpixel 101 as the emission light from the light emitting surface (set as the emission color) may be provided as the plurality of light emitting elements 104. The light emitting elements 104 corresponding to the subpixels 101R, 101G, and 101B are referred to as light emitting elements 104R, 104G, and 104B, respectively. Furthermore, the plurality of light emitting elements 104 has a layout corresponding to the arrangement of the subpixels 101 of each color type. Note that, in the present specification, in a case where the types such as the light emitting elements 104R, 104G, and 104B are not particularly distinguished, the term light emitting element 104 is used. The layout of the plurality of light emitting elements 104 is not particularly limited, but may be two-dimensionally arranged in, for example, a stripe-shaped arrangement pattern or a delta-shaped arrangement pattern.

As illustrated in FIG. 8, the light emitting element 104 has a laminated structure in which a first electrode 13, an organic layer 14, and a second electrode 15 are laminated in this order. The first electrode 13, the organic layer 14, and the second electrode 15 are laminated in this order from the drive substrate 11 side in a direction from the second surface toward the first surface (+Z direction).

### First Electrode

A plurality of the first electrodes 13 is provided on the first surface side of the substrate 11A. In the example of FIG. 8, the first electrode 13 is an anode electrode.

The first electrode 13 includes at least one of a metal layer or a metal oxide layer. The first electrode 13 may be constituted by a single-layer film of a metal layer or a metal oxide layer, or a laminated film of a metal layer and a metal oxide layer.

The metal layer contains, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the at least one metal element as a constituent element of the alloy. Specific examples of the alloy include an aluminum alloy and a silver alloy. Specific examples of the aluminum alloy include AlNd and AlCu.

The metal oxide layer contains, for example, at least one of a mixture of indium oxide and tin oxide (ITO), a mixture of indium oxide and zinc oxide (IZO), or titanium oxide (TiO).

In the display apparatus 10, the first electrode 13 is electrically separated for each subpixel 101. That is, a plurality of the first electrodes 13 is provided on the first surface side of the drive substrate 11, and is provided for each subpixel 101.

In addition, preferably, an insulating layer is formed between the adjacent first electrodes 13. For example, the inorganic insulating layer 11B may be formed between the adjacent first electrodes 13. In this case, the inorganic insulating layer 11B electrically separates each first electrode 13 for each light emitting element 104 (that is, for each subpixel 101). In addition, an opening 12 is formed on the first surface side of the inorganic insulating layer 11B, the first surface (the surface facing the second electrode 15) of the first electrode 13 is exposed from the opening of the inorganic insulating layer 11B, and a portion of the first electrode 13 exposed from the opening 12 of the inorganic insulating layer 11B faces the organic layer 14 described later while avoiding interposition of the inorganic insulating layer 11B.

### Organic Layer

The organic layer 14 is an organic light emitting layer provided between the first electrode 13 and the second electrode 15. The organic layer 14 may be provided as a layer common to the subpixels 101. For example, the organic layer 14 is common to the subpixels 101R, 101G, and 101B, and may be configured to be able to emit white light. However, this does not prohibit that the emission color of the organic layer 14 is other than white, and colors such as red, blue, and green may be adopted. That is, the emission color of the organic layer 14 may be, for example, any one of white, red, blue, and green.

The organic layer 14 has, for example, a configuration in which a hole injection layer, a hole transport layer, a light emitting layer, and an electron transport layer are laminated in this order from the first electrode 13 toward the second electrode 15. An electron injection layer may be provided between the electron transport layer and the second electrode 15. The electron injection layer is for enhancing electron injection efficiency. Note that the configuration of the organic layer 14 is not limited thereto, and layers other than the light emitting layer are provided as necessary.

The hole injection layer is a buffer layer for enhancing hole injection efficiency into the light emitting layer and suppressing leakage. The hole transport layer is for enhancing hole transport efficiency to the light emitting layer. The electron transport layer is for enhancing electron transport efficiency to the light emitting layer.

The light emitting layer generates light by recombination of electrons and holes by applying an electric field. The light emitting layer is an organic compound layer containing an organic light emitting material.

### Second Electrode

The second electrode 15 is provided on the upper side of the organic layer 14. A portion of the second electrode 15 corresponding to the subpixel 101 (a portion corresponding to the light emitting element 104) is provided so as to face the first electrode 13. The second electrode 15 is provided as an electrode common to the plurality of subpixels 101. The second electrode 15 is a cathode electrode. The second electrode 15 is preferably a transparent electrode having transparency to light generated in the organic layer 14. The transparent electrode referred to herein includes a transparent electrode constituted by a transparent conductive layer and a transparent electrode constituted by a laminated structure having a transparent conductive layer and a semi-transmissive reflective layer.

As the transparent conductive layer, a transparent conductive material having good optical transparency and a small work function is suitably used. The transparent conductive layer can be constituted by, for example, a metal oxide. Specifically, examples of the material of the transparent conductive layer can include a material containing at least one of a mixture of indium oxide and tin oxide (ITO), a mixture of indium oxide and zinc oxide (IZO), or zinc oxide (ZnO).

The semi-transmissive reflective layer can be constituted by, for example, a metal layer. Specifically, examples of the material of the semi-transmissive reflective layer can include a material containing at least one metal element selected from the group consisting of magnesium (Mg), aluminum (Al), silver (Ag), gold (Au), and copper (Cu). The metal layer may contain the at least one metal element as a constituent element of the alloy. Specific examples of the alloy include an MgAg alloy and an AgPdCu alloy.

### Covering Structure

The display structure 103 has the covering structure 105 as described above. The covering structure 105 indicates a layer structure formed so as to cover the formation surface side (first surface) of the light emitting element 104. In the example of FIG. 8, the covering structure 105 includes a protective layer 16 and a counter substrate 22.

### Protective Layer

The protective layer 16 preferably has a layer structure formed so as to cover the light emitting element 104 on the first surface side of the light emitting element 104. The protective layer 16 makes it difficult for the first surface of the light emitting element 104 to come into contact with the outside air, and suppresses moisture ingress into the light emitting element 104 from the external environment.

The protective layer 16 is constituted by an insulating material. As the insulating material, for example, an inorganic compound such as Sio, SiON, AlO, or TiO can be suitably used. Examples of the protective layer 16 include a CVD film containing SiO, SiON, or the like, and an ALD film containing AlO, TiO, Si, or the like. Note that the CVD film indicates a film formed using chemical vapor deposition. The ALD film indicates a film formed using atomic layer deposition. The protective layer 16 may be constituted by a single layer or may have a structure in which a plurality of layers is laminated.

### Counter Substrate

In the display region 10A, a surface layer 107 forming an outermost surface of the display panel 100 is provided, and in the example of FIG. 2, a counter substrate 22 is provided as the surface layer 107. The counter substrate 22 is provided on the first surface side of the protective layer 16, and the material of the counter substrate 22 can be the material of the substrate 11A or the like. For example, a glass substrate can be used as the counter substrate 22. The material of the glass substrate is not particularly limited as long as it is constituted by a material that transmits light emitted from the light emitting element 104. Examples of the material of the glass substrate include various glass substrates such as high strain point glass, soda glass, borosilicate glass, and lead glass, and quartz substrates.

### Filling Resin Layer

In the display region 10A, as illustrated in FIG. 8, a filling resin layer 19 is preferably provided between the protective layer 16 and the counter substrate 22. By providing the filling resin layer 19, the first surface sides of the light emitting element 104 and the protective layer 16 can be smoothed, and the light emitting element 104 can be protected from the outside air and moisture. The filling resin layer 19 is preferably a layer having a function as a transparent adhesive layer. As a material of the filling resin layer 19, an organic material such as various resin materials may be used.

### Sealing Layer

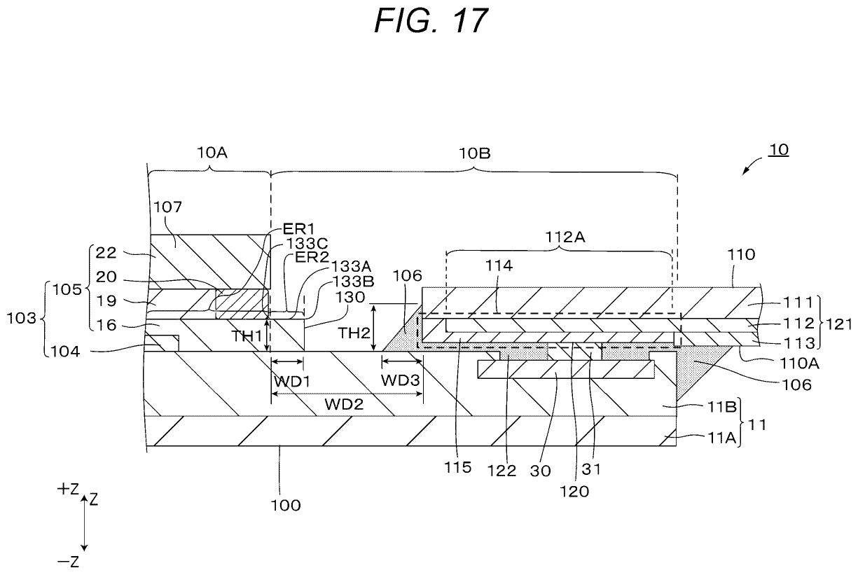

Between the protective layer 16 and the counter substrate 22, a sealing layer 20 may be provided around the filling resin layer 19 as illustrated in FIG. 17 and the like used in the description below, or may be omitted.

### Other Layers

Note that the covering structure 105 may include a layer (other layer) different from the above-described protective layer 16 and the like on the first surface side of the protective layer 16 and between the protective layer 16 and the surface layer 107 (between the protective layer 16 and the filling resin layer 19 in a case where the filling resin layer 19 is formed). Examples of the other layer include the organic functional layer 108 containing an organic compound. Examples of the organic functional layer 108 containing an organic compound include a planarization layer 21 and a wavelength selective layer as illustrated in FIG. 8.

### Planarization Layer

The planarization layer 21 covers at least a part of the protective layer 16. The planarization layer 21 is preferably constituted by a material having excellent hygroscopicity.

### Wavelength Selective Layer

As the wavelength selective layer, a color filter 18 and the like can be exemplified as illustrated in FIG. 8. An on-chip color filter (OCCF) can be exemplified as the color filter 18. The color filter 18 may be provided according to the color type of the subpixel 101. Examples of the color filter 18 include a red color filter (red filter 18R), a green color filter (green filter 18G), and a blue color filter (blue filter 18B). The red filter 18R, the green filter 18G, and the blue filter 18B are provided in the subpixels 101R, 101G, and 101B, respectively.

Since the color filter 18 is provided, it is easy to set the light generated from the organic layer 14 to the color type corresponding to the subpixel.

### Lens

Furthermore, the lens described above as an example of other layers is preferably provided in a layout corresponding to each subpixel 101. The lens is preferably an on-chip lends (OCL).

The shape of the lens is not particularly limited. As the lens, a lens (so-called convex lens) formed in a convex shape having a curved surface convexly curved on the first surface side can be exemplified. Since the lens is provided in the display panel, it is easier to adjust the light generated from the light emitting element 104 to be emitted from the predetermined portion of the display region 10A, and the utilization efficiency of the light can be improved.

### 1-2 Operation and Effects

As a structure for electrically connecting a display panel and a flexible printed circuit in a conventional display apparatus, there is provided a technique for electrically connecting an external electrode of the display panel and a connection wiring of the flexible printed circuit via an anisotropic conductive film. In the technique using the anisotropic conductive film, it is often required to increase the facing area between the external electrode and the anisotropic conductive film in order to reduce the resistance value by the anisotropic conductive film, and the ratio of the display region to the display panel is likely to be limited.

In addition, since it is required to cure the anisotropic conductive film by performing a heat treatment at a relatively high temperature, it has been pointed out that the light emitting element of the display panel may be damaged during the heat treatment. In a case where the light emitting element is an organic EL element, it has been particularly required to suppress damage to the light emitting element in the display panel due to heat.

According to the display apparatus 10 illustrated in the first embodiment, the bump electrode 31 is formed on the external electrode 30, and the bump electrode 31 and the connection wiring 114 are connected. A metal is suitably used as a material of the bump electrode 31, and a connection portion between the bump electrode 31 and the connection wiring 114 is a metal bonding portion 120. In addition, in a case where the bump electrode 31 is constituted by a stud bump, the size of the bump electrode 31 can be reduced to about 100 um in diameter, so that the size of the external electrode 30 can also be reduced. Therefore, according to the first embodiment, as compared with the case where the display panel and the flexible printed circuit are connected using the anisotropic conductive film as described above, the size of the external electrode 30 can be reduced, the size of the outer region 10B of the display panel 100 can be reduced, and the ratio of the display region 10A to the display panel 100 can be improved.

According to the display apparatus 10 of the first embodiment, since the connection portion between the bump electrode 31 and the connection wiring 114 is the metal bonding portion 120, the resistance value of the connection portion between the external electrode 30 and the connection wiring 114 is reduced, the power loss at the connection portion between the external electrode 30 and the connection wiring 114 is suppressed, and the low power consumption of the display panel 100 can be realized as compared with the case where the display panel and the flexible printed circuit are connected using the anisotropic conductive film as described above.

In addition, in the display apparatus illustrated in the first embodiment, since the metal bonding portion 120 may be formed by ultrasonic bonding, it is possible to make the light emitting element 104 less likely to be damaged by heat as compared with the case of connecting the display panel and the flexible printed circuit using the anisotropic conductive film as described above.

Next, a modification of the first embodiment will be described.

### 1-3 Modification

### Modification 1

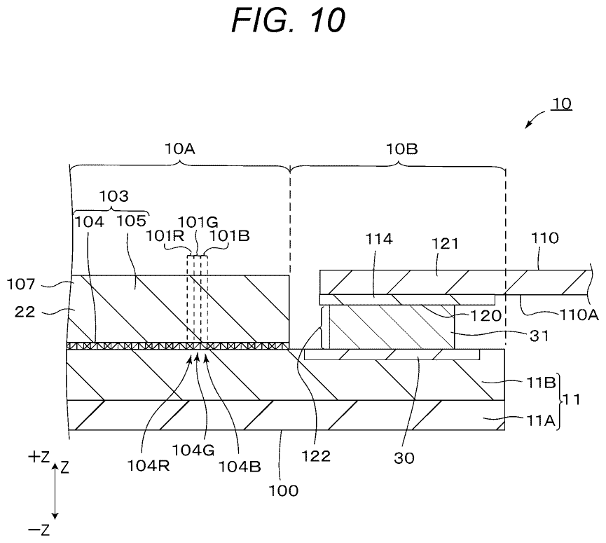

In the example of the display apparatus 10 according to the first embodiment illustrated in the example of FIG. 2, the bump electrode 31 is a stud bump, but the bump electrode 31 is not limited thereto. As illustrated in FIG. 10, the bump electrode 31 in the display apparatus 10 according to the first embodiment may be a bump formed by a plating method. This form is referred to as Modification 1 of the first embodiment. FIG. 10 is a cross-sectional view schematically illustrating one of examples of a display apparatus 10 according to Modification 1 of the first embodiment.

### Bump

In Modification 1 of the first embodiment, for example, an electroless plating method may be adopted as a plating method for forming a bump to be the bump electrode 31.

In a case where the bump electrode 31 is a bump formed by a plating method, the material of the bump electrode 31 (that is, the material of the bump) is preferably selected according to the material of the external electrode 30. For example, in a case where the material of the external electrode 30 is aluminum (in a case where the external electrode is an aluminum electrode), gold can be suitably employed as the material of the bump electrode 31 from the viewpoint that metal can be deposited in a state of being attached onto the external electrode 30.

### Bump Forming Method

A method for forming a bump by an electroless plating method will be described. First, pretreatment for preventing formation of an oxide film is performed on the first surface of the external electrode 30 of the display panel 100. The pretreatment is a substitution treatment of the surface on the first surface side of the external electrode 30. Examples of the substitution treatment include a treatment (zincate treatment) of subjecting the external electrode 30 to zinc substitution in a case where the external electrode is an aluminum electrode. In this case, a zinc film is formed as a metal film on the first surface of the external electrode 30. In addition, the substitution treatment may be a treatment of forming a film of Pd as a metal film on the first surface side of the external electrode 30. Note that, in a case where the external electrode 30 is an aluminum electrode, a natural oxide film (passive) may be formed on the surface (first surface) of the external electrode 30. In such a case, the pretreatment described above is removed after the natural oxide film is removed. Examples of a method of removing the natural oxide film include a method of removing the natural oxide film with an etching solution. Examples of the etching solution include sodium hydroxide and phosphoric acid.

The display panel 100 subjected to the pretreatment is immersed in an electroless plating solution. At this time, the metal film deposited by the substitution reaction is dissolved, and the metal forming the bump is deposited on the first surface of the external electrode 30. Then, by immersing the display panel in the electroless plating solution for a predetermined time, metal is deposited to a predetermined film thickness, and the metal structure having the predetermined film thickness becomes a bump as the bump electrode 31.

Although the case where the bump is formed by the electroless plating method has been described above, the bump is not limited to the case where the bump is formed by such a method, and may be formed by the electrolytic plating method. In the electrolytic plating method, the display panel 100 is immersed in an electrolytic solution for electrolytic plating, and a metal to be plated is deposited on the external electrode 30 by passing electricity therethrough, whereby formation of a bump can be realized.

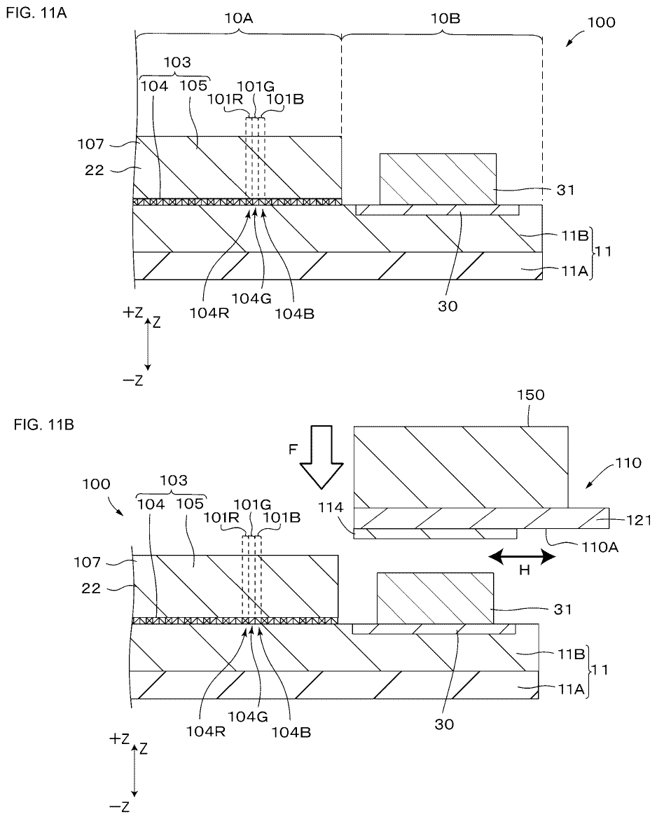

Note that, even in a case where the bump electrode 31 is a bump formed by a plating method, a bonding portion between the bump electrode 31 and the connection wiring 114 of the flexible printed circuit 110 is formed as the metal bonding portion 120. In addition, as a method of forming the metal bonding portion 120, a method of preparing the display panel 100 as illustrated in FIG. 11A, holding the flexible printed circuit 110 by the head 150 as illustrated in FIG. 11B, and ultrasonically bonding the display panel and the flexible printed circuit 110 can be adopted. For ultrasonic bonding, ultrasonic bonding as described above with reference to FIGS. 4 and 5 is suitably used.

### Modification 2

In the display apparatus 10 according to the first embodiment, in a case where the gap 122 between the flexible printed circuit 110 and the display panel 100 is filled with the underfill material, that is, in a case where the sealing structure 106 is formed, as illustrated in FIG. 7, the sealing auxiliary layer 123 may be formed so as to cover the outer surface (the outer peripheral surface of the sealing structure 106) of the portion formed with the underfill material. This mode is referred to as Modification 2 of the first embodiment. FIG. 7 is a cross-sectional view schematically illustrating one of examples of a display apparatus 10 according to Modification 2 of the first embodiment.

### Sealing Auxiliary Layer

In the example of FIG. 7, the sealing auxiliary layer 123 is formed so as to cover the outer peripheral surface of the sealing structure 106 along the outer peripheral surface of the sealing structure 106.

The sealing auxiliary layer 123 may cover the outer peripheral surface of the sealing structure 106, and may cover the outer end surface of the inorganic insulating layer 11B or the substrate 11A, or may further cover a part of the flexible printed circuit 110 (a portion corresponding to a region not facing the display panel 100). In addition, since the sealing auxiliary layer 123 is formed, it is possible to more effectively reduce the possibility that the structure of the metal bonding portion 120 is broken by the action of external stress. In addition, it is possible to more effectively suppress the possibility that moisture intrudes from the outside of the display panel 100. The sealing auxiliary layer 123 can be constituted by a resin material or the like, but the resin material for forming the sealing auxiliary layer 123 is preferably a different type of resin from the resin material for forming the sealing structure 106. The sealing auxiliary layer 123 can be formed, for example, by applying a resin material in a direction of an arrow HD2 in FIG. 7 and curing the resin material.

### Modification 3

In the display apparatus 10 according to the first embodiment, the layout of the external electrodes is not limited to the layout illustrated in the example of FIG. 12A, and for example, as illustrated in FIGS. 12B and 12C, the external electrodes 30 adjacent to each other in the direction along the direction in which one side of the display region 10A extends may be laid out so as to be shifted from each other. Such a form is referred to as Modification 3 of the first embodiment. FIGS. 12B and 12C are plan views schematically illustrating one example of a display apparatus according to Modification 3 of the first embodiment.

### Layout of External Electrode

In the layout of the external electrodes 30 illustrated in the example of FIG. 12B, the layout of the external electrodes 30 is determined so that the plurality of external electrodes 30 is arranged in a staggered manner in a direction (in the example of FIG. 12B, a direction along one side of counter substrate 22) along the extending direction of one side of the display region 10A. In a case where the external electrodes 30 have a staggered layout as illustrated in FIG. 12B, the external electrodes can be formed such that the external electrodes electrically connected to the respective connection wirings do not overlap each other even if the separation distance between the adjacent connection wirings on the flexible printed circuit 110 becomes short, and the external electrodes can be formed more densely inside the outer region 10B, and the utilization efficiency of the outer region 10B can be improved. Therefore, even if the outer region 10B is a limited region, more connection portions between the external electrodes and the connection wiring can be formed.

In addition, the layout of the external electrodes 30 illustrated in the example of FIG. 12C is a layout in which combinations of the plurality of external electrodes 30 arranged in an oblique direction with respect to the direction away from the display region 10A are arranged in a direction along the extending direction of one side of the display region 10A. Note that a layout determined by a combination of the plurality of external electrodes 30 aligned in an oblique direction with respect to the direction away from the display region 10A is referred to as a stepwise layout. In the example of FIG. 12C, as a combination of the plurality of external electrodes 30 arranged in a stepwise layout, a combination of three external electrodes 30 (external electrodes 30A, 30B, and 30C) is arranged in a direction along an extending direction of one side of the display region 10A. In a case where the external electrodes 30 have a stepwise layout as described above, similarly to the case where the external electrodes 30 have a staggered layout as described above, the external electrodes can be formed such that the external electrodes electrically connected to the respective connection wirings 114 do not overlap each other even if the separation distance between the adjacent connection wirings 114 on the flexible printed circuit 110 is shortened.

### Modification 4

In the display apparatus 10 according to the first embodiment, the surface layer 107 is not limited to the case of the counter substrate 22, and an overcoat layer 23 may be provided as the surface layer 107 instead of the counter substrate 22 as illustrated in the example of FIG. 23 used in the description of the embodiment to be described later. Such a form is referred to as Modification 4 of the first embodiment.

### Overcoat Layer

In the display apparatus 10 according to Modification 4 of the first embodiment, the overcoat layer 23 is formed on the first surface side of the protective layer 16 so as to cover the protective layer 16. The overcoat layer 23 is preferably constituted by an inorganic layer such as a layer constituted by a light-transmissive resin material or a film constituted by an inorganic material. In addition, as a resin material for forming the overcoat layer 23, a hard coat agent such as an ultraviolet curable resin or a thermosetting resin can be adopted. Furthermore, as the inorganic layer, a film or the like formed by using a method such as spin on glass (SOG), CVD, or sputtering can be adopted. As the inorganic material constituting the inorganic layer, a material applicable to these methods can be adopted. In a case where the surface layer 107 is the overcoat layer 23, the filling resin layer 19 and the sealing layer 20 can be omitted.

Modifications 2 to 4 described above may be applied to any of the second to sixth embodiments described later. Modification 1 may be applied to any of the fourth to sixth embodiments described later.

### 2 Second Embodiment

### 2-1 Configuration

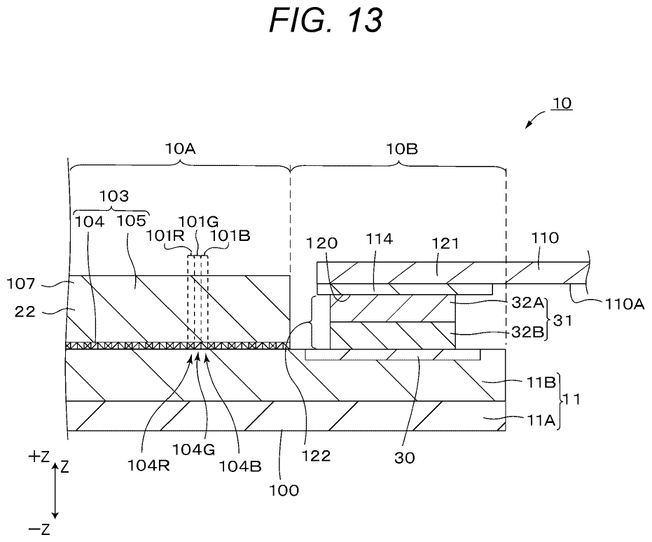

The display apparatus 10 according to the second embodiment has the same configuration as the display apparatus of the first embodiment except that the bump electrode 31 is constituted by a laminate in which a plurality of metal layers 32 is laminated as illustrated in FIG. 13. FIG. 13 is a cross-sectional view illustrating an example of the display apparatus according to the second embodiment. Note that, in the following description of the second embodiment, the description of a configuration similar to that of the first embodiment is omitted.

### Bump Electrode

In the display apparatus 10 according to the second embodiment, the bump electrode 31 provided on the first surface of the external electrode 30 is constituted by a laminate in which a plurality of metal layers 32 is laminated as described above. The metals constituting the metal layers 32 in contact with each other forming the laminate are different from each other.

In the example of FIG. 13, the bump electrode 31 includes a metal layer 32 (first metal layer 32A) forming an outermost surface 31A on the upper surface side (outermost surface on the first surface side), and a metal layer 32 (second metal layer 32B) facing the lower surface (second surface) of the first metal layer 32A, and is a laminate of the first metal layer 32A and the second metal layer 32B. Note that this is an example, and the bump electrode 31 may be a laminate of three or more metal layers 32. In addition, in the example of FIG. 13, the first metal layer 32A is laminated on the first surface of the second metal layer 32B, but the first metal layer 32A may be formed as a layer covering not only the first surface of the second metal layer 32B but also the side peripheral surface of the second metal layer 32B. Note that, in the present specification, in a case where the first metal layer 32A and the second metal layer 32B are not distinguished, they are collectively referred to as metal layers 32.

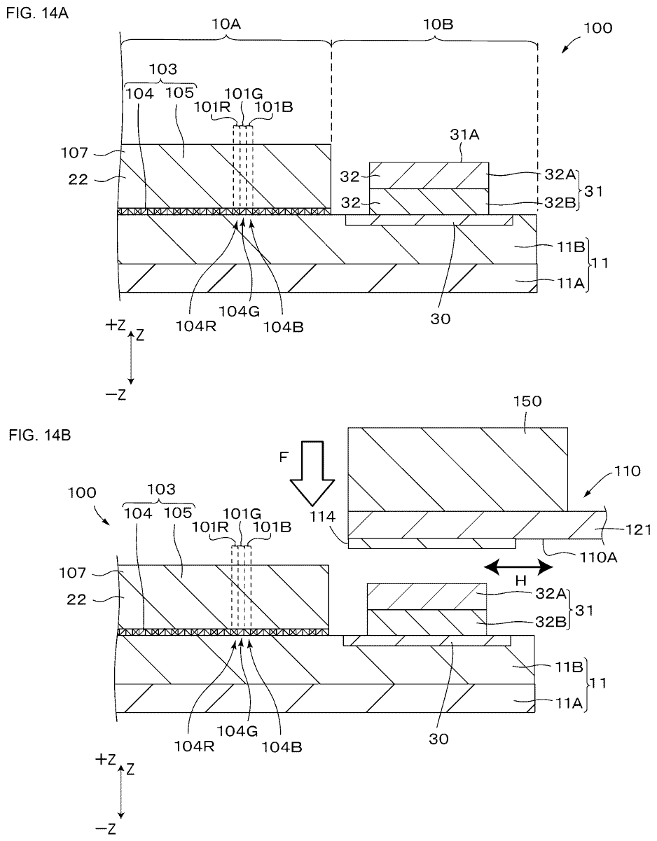

In the display apparatus 10 according to the second embodiment, similarly to the first embodiment, the bump electrode 31 is bonded to the connection wiring 114 of the flexible printed circuit 110 by ultrasonic bonding as illustrated in FIGS. 14A and 14B. As illustrated in FIG. 14A, the display panel 100 is prepared. Then, as illustrated in FIG. 14B, similarly to the first embodiment, the flexible printed circuit 110 to which the head 150 is attracted is disposed at a predetermined position of the display panel 100, and the first metal layer 32A of the bump electrode 31 is bonded to the connection wiring 114 by ultrasonic bonding. In the display apparatus 10 according to the second embodiment, the bonding portion between the first metal layer 32A and the connection wiring 114 is the metal bonding portion 120. FIGS. 14A and 14B are cross-sectional views for explaining an example of a process of bonding the bump electrode 31 of the display panel 100 and the connection wiring 114 of the flexible printed circuit 110 by ultrasonic bonding in the display apparatus 10 according to the second embodiment.

In the bump electrode 31, metals constituting the metal layers 32 in contact with each other forming the laminate are different from each other.

The metal layer 32 (in the example of FIG. 13, the first metal layer 32A and the second metal layer 32B) constituting the bump electrode 31 is a layer (plating layer) formed by a plating method. The plating method for forming the metal layer 32 may be an electroless plating method or an electrolytic plating method.

The first metal layer 32A is preferably constituted by a metal selected from the group of metal species including gold, silver, and copper. Since the first metal layer 32A forming the outermost surface 31A is constituted by a metal type selected from these metal groups, it is possible to realize a reduction in resistance in the metal bonding portion 120 which is a bonding portion between the bump electrode 31 and the connection wiring 114 of the flexible printed circuit 110. In addition, since the first metal layer 32A is constituted by a metal type selected from these metal groups, it is possible to improve the bondability between the bump electrode 31 and the connection wiring 114 of the flexible printed circuit 110. In addition, gold can be suitably used for the first metal layer 32A from the viewpoint of not causing metal oxidation.

The second metal layer 32B is a layer that can be formed on the first surface of the external electrode 30 by a plating method. The metal species for forming the second metal layer 32B may be determined according to the material of the external electrode 30. For example, in a case where the external electrode 30 is an aluminum electrode, a layer constituted by nickel can be suitably employed as the second metal layer 32B.

### Method of Forming Bump Electrode

The bump electrode 31 can be obtained by forming the second metal layer 32B on the first surface of the external electrode 30 by a plating method, and further forming the first metal layer 32A on the second metal layer 32B (or by coating the second metal layer 32B with the first metal layer 32A) by a plating method. Note that, as the plating method, either the electroless plating method or the electrolytic plating method may be used as described above. Since the electroless plating method and the electrolytic plating method can be performed by a method similar to that described in the bump forming method in Modification 1 of the first embodiment, the detailed description thereof is omitted.

### 2-2 Operation and Effects

According to the display apparatus according to the second embodiment, effects similar to those of the first embodiment can be obtained.

### 3 Third Embodiment

### 3-1 Configuration

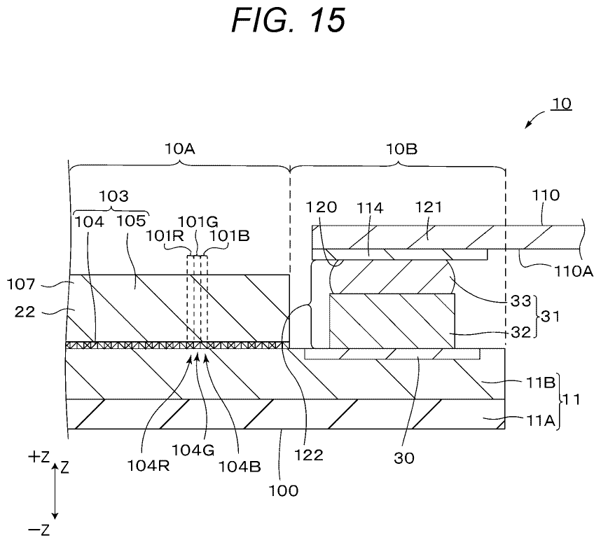

As illustrated in FIG. 15, the display apparatus 10 according to the third embodiment has the same configuration as the display apparatus 10 according to the second embodiment except that the metal layer 32 forming the outermost surface 31A on the upper surface side of the bump electrode 31 (outermost surface on the first surface side) is the solder layer 33. FIG. 15 is a cross-sectional view illustrating an example of the display apparatus 10 according to the third embodiment. Note that, in the following description of the third embodiment, the description of a configuration similar to that of the first embodiment is omitted.

### Bump Electrode

In the display apparatus 10 according to the third embodiment, as described in the second embodiment, the bump electrode 31 provided on the first surface of the external electrode 30 is constituted by a laminate in which a plurality of metal layers 32 is laminated.

In the example of FIG. 15, the bump electrode 31 includes a metal layer forming an outermost surface 31A on an upper surface side thereof and a metal layer 32 facing a lower surface (second surface) of the metal layer, and is a laminate of a plurality of metal layers.

The metal layer forming the outermost surface 31A of the bump electrode 31 is a layer (solder layer 33) constituted by solder. The solder forming the solder layer 33 preferably contains at least one metal selected from the group of metal species consisting of indium and bismuth. Since the solder forming the solder layer 33 contains at least one of indium or bismuth, the melting point of the solder can be relatively lowered. For example, a solder containing no indium or bismuth often has a melting point of 200° C. or higher. However, a solder containing indium can suppress the melting point to about 156° C., and a solder containing bismuth can suppress the melting point to about 138° C. The metal layer 32 facing the lower surface of the solder layer 33 may be a plating layer similar to the second metal layer 32B described in the second embodiment described above, and thus a detailed description thereof will be omitted.

### Method of Forming Bump Electrode

The bump electrode 31 can be obtained by forming the metal layer 32 on the first surface of the external electrode 30 by a plating method, and further forming the solder layer 33 on the metal layer 32 (or so as to cover the metal layer 32). Note that, as the plating method, either the electroless plating method or the electrolytic plating method may be used as described above. Since the electroless plating method and the electrolytic plating method can be performed by a method similar to that described in the bump forming method in Modification 1 of the first embodiment, the detailed description thereof is omitted. As a method for forming the solder layer 33, for example, a method can be used in which a state in which heated and melted solder is disposed on the upper surface of the metal layer 32 is formed, and the solder layer 33 is formed by solidification of the solder accompanying cooling of the melted solder.

### Method for Forming Metal Bonding Portion

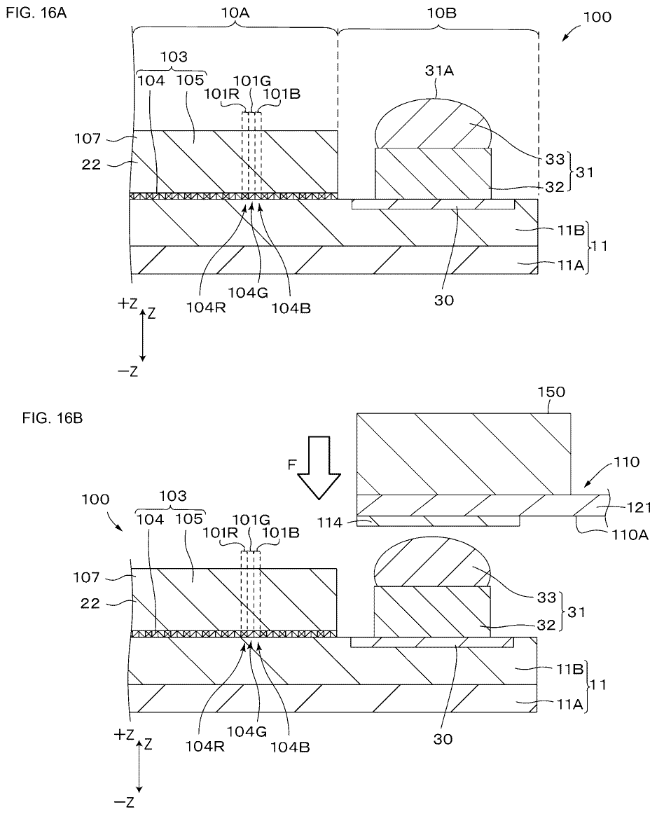

In the third embodiment, as illustrated in FIGS. 16A and 16B, the metal bonding portion 120 is formed by soldering the connection wiring 114 and the bump electrode 31 using heating and pressurization to the bump electrode 31 of the display panel 100. As illustrated in FIG. 16A, the display panel 100 is prepared. Then, as illustrated in FIG. 16B, the flexible printed circuit 110 attracted to the head 150 is disposed at a predetermined position of the display panel 100. Then, the connection wiring 114 of the flexible printed circuit 110 and the solder layer 33 of the bump electrode 31 are heated to dissolve the solder layer 33, and the connection wiring 114 and the solder layer 33 are pressurized to bond the connection wiring 114 and the solder layer 33 (soldering processing). At this time, the metal bonding portion 120 is formed. Note that, as described above, in a case where the solder layer 33 is constituted by solder containing at least one of indium or bismuth, the heating temperature in the soldering processing may be relatively low, so that damage to the light emitting element 104 of the display panel 100 due to heat can be made less likely to occur.

### 3-2 Operation and Effects

According to the display apparatus 10 according to the third embodiment, similar to the second embodiment, it is possible to obtain an effect similar to the effect of the first embodiment.

### 4 Fourth Embodiment

### 4-1 Configuration

As illustrated in FIG. 17, the display apparatus according to the fourth embodiment has the same configuration as that of the first to third embodiments except that a gap 122 between a display panel 100 and a flexible printed circuit 110 is filled with an underfill material (sealing structure 106), and a bank structure 130 (bank) is formed between an external electrode 30 and a display region 10A in the display panel 100. FIG. 17 is a cross-sectional view for explaining an example of the display apparatus according to the fourth embodiment. FIG. 17 illustrates an example of a case where the other configuration except for the bank structure 130 has a configuration similar to that of the first embodiment. In the example of FIG. 17, the display apparatus 10 includes a substrate 11A and a covering structure 105 that covers the light emitting element 104 provided on the upper side of the substrate 11A, and the covering structure 105 includes at least a surface layer 107 that forms the outermost surface of the covering structure 105 and a protective layer 16 that is disposed at a position closer to the light emitting element 104 than the surface layer 107 and contains an inorganic compound. In addition, a filling resin layer 19 is formed between the surface layer 107 and the protective layer 16, and a sealing layer 20 is formed so as to cover an outer wall surface of the filling resin layer 19. Note that, in the following description of the fourth embodiment, the description of a configurations similar to those of the first to third embodiments such as the light emitting element 104 and the surface layer 107 will be omitted.

### Bank Structure

The bank structure 130 (bank) is a structure that forms a step at a position between the external electrode 30 and the display region 10A in plan view of the display apparatus 10, and has at least one layer that forms the covering structure 105. The upper surface (first surface) of the bank structure 130 is located above the upper surface of the drive substrate 11 (the upper surface (first surface) of the inorganic insulating layer 11B), and the outer wall surface of the bank structure 130 rises from the upper surface of the drive substrate 11. In a case where the display apparatus 10 according to the fifth embodiment includes the counter substrate 22, the layer forming the bank structure 130 is a layer avoiding a layer in direct contact with the counter substrate 22 among the layers forming the covering structure 105. Examples of the layer in direct contact with the counter substrate 22 include the filling resin layer 19 and the sealing layer 20 in the example of FIG. 17. The filling resin layer 19 and the sealing layer 20 are preferably excluded from the target of the layer forming the bank structure 130 from the viewpoint of being easily constituted by a material that easily receives moisture as compared with the layer excluding the filling resin layer and the sealing layer (for example, the protective layer 16 and the like). In the example of FIG. 17, the bank structure 130 includes at least a part of the protective layer 16 among the layers constituting the covering structure 105. In addition, the upper surface 133A of the bank structure 130 is located below the upper surfaces of the filling resin layer 19 and the sealing layer 20, and the outer end 133B (end portion away from the display region 10A) of the bank structure 130 is located at a position between the sealing layer 20 and the external electrode 30 in plan view of the display apparatus 10. In a case where the sealing layer 20 is omitted, the outer end 133B of the bank structure 130 is located at a position between the filling resin layer 19 and the external electrode 30.

The dimension of the bank structure 130 may be determined according to the distance between the display region 10A and the flexible printed circuit 110 and the size of the gap 122, and is not particularly limited as long as the outer end 133B of the bank structure 130 is located between the external electrode 30 and the display region 10A. For example, the thickness (TH1 in FIG. 17) of the bank structure 130 may be about 2 μm, and the length of the bank structure 130 (the distance (WD1 in FIG. 17) from the end portion (inner end 133C) on the display region 10A side to the outer end 133B may be about 25 μm. In this example, the distance (WD2 in FIG. 17) between the display region 10A and the flexible printed circuit 110 may be about 200 μm. Even in a case where the underfill material overflows from the gap 122 to the display region side, the length of the overflowing portion (separation (WD3 in FIG. 17) flowing from the inner end of the region where the flexible printed circuit and the display panel face each other toward the display region is often about 170 μm or less, and the height of the overflowing portion (TH2 in FIG. 17) is often about 100 μm or less. Therefore, if the distance between the display region 10A and the flexible printed circuit 110 and the dimensions of the bank structure 130 are substantially secured to the above-described values, it is possible to substantially suppress the underfill material from entering the display region 10A side along the bank structure 130.

### Protective Layer

In the display apparatus according to the fourth embodiment illustrated in the example of FIG. 17, the protective layer 16 has a structure extending from the display region 10A to a part of the outer region 10B, and includes a portion ER1 formed in the display region 10A and a portion ER2 formed in a part of the outer region 10B. In the example of FIG. 17, the portion ER2 of the protective layer 16 is continuously connected to the portion ER1, but this is an example. In addition, the portion ER2 of the protective layer 16 forms a bank structure 130. The outer end of the protective layer 16 rises from the upper surface of the drive substrate 11 and corresponds to the outer end 133B of the bank structure 130. In the display apparatus illustrated in the example of FIG. 17, the position of the outer end of the protective layer 16 is a position between the display region 10A and the external electrode 30 in plan view of the display apparatus 10.

### Sealing Structure

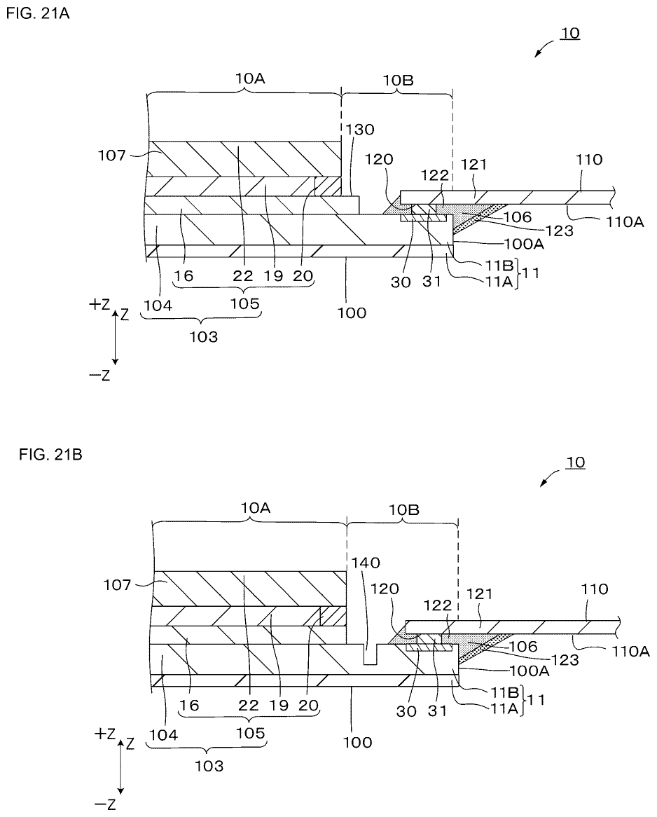

In the display apparatus 10 according to the fourth embodiment illustrated in the example of FIG. 17, the sealing structure 106 is formed as described in the first embodiment, but as illustrated in FIG. 21A, the sealing auxiliary layer 123 may be formed so as to cover the outer surface of the sealing structure 106. FIG. 21A is a cross-sectional view for explaining an example in a case where the sealing auxiliary layer 123 is formed in the sealing structure 106 in the display apparatus 10 according to the fourth embodiment.

### 4-2 Operation and Effects

In the display apparatus 10 according to the fourth embodiment, the gap 122 between the display panel 100 and the flexible printed circuit 110 is filled with an underfill material. In a case where filling the gap 122 with the underfill material is realized by drawing the underfill material using the capillary phenomenon in the gap 122 between the flexible printed circuit 110 and the display panel 100 as described in the first embodiment, the viscosity of the underfill material is often suppressed from the viewpoint of effectively causing the capillary phenomenon. When the viscosity of the underfill material is suppressed, a state in which the underfill material does not fall within the gap 122 and overflows from the gap 122 to the outside is likely to be formed. At this time, in a case where the underfill material overflowing from the gap 122 to the outside flows toward the display region 10A, the underfill material may enter the display region 10A, for example, the underfill material may enter the second surface side at the interface between the filling resin layer 19 or the sealing layer 20 and the layer adjacent thereto.

According to the display apparatus 10 according to the fourth embodiment, the bank structure 130 is formed between the display region 10A and the external electrode 30. Therefore, in a case where the underfill material overflowing outward from the gap 122 between the flexible printed circuit 110 and the display panel 100 travels toward the display region 10A, the bank structure 130 can function as an interference wall that suppresses the progress of the underfill material. In addition, in order for the underfill material to reach the display region 10A, the underfill material needs to pass over the side end surface of the outer end 133B of the bank structure 130, reach the upper surface of the bank structure 130, and further move along the upper surface of the bank structure 130 to the display region 10A. Therefore, according to the display apparatus 10 according to the fourth embodiment, it is possible to extend the moving distance required for the underfill material to reach (reaches the outer wall surface of the counter substrate 22, the outer wall surface of the filling resin layer 19, or the outer wall surface of the sealing layer 20) the display region 10A, as compared with a case where the bank structure 130 is not present. Therefore, according to the display apparatus 10 according to the fourth embodiment, it is possible to effectively suppress the possibility that the underfill material overflowing to the outside from the gap 122 between the flexible printed circuit 110 and the display panel 100 enters the display region 10A side.

In addition, in order to prevent the underfill material from entering the display region in a case where the underfill material overflowing to the outside from the gap between the flexible printed circuit and the display panel flows to the display region side, it is conceivable to separately provide a dam structure on the drive substrate using resin or the like between the display region and the external electrode. However, in a case where a dam structure is separately formed using a resin or the like, there is a possibility that a process or a material for providing the dam structure is newly required. In addition, in a case where a resin is used, there is a possibility that dimensional stability of the dam structure becomes insufficient, and there is a possibility that downsizing of the display apparatus becomes difficult.

According to the display apparatus 10 according to the fourth embodiment, the bank structure 130 can be constituted by the protective layer 16 constituting the covering structure 105, and the protective layer 16 can be constituted by an inorganic compound. Therefore, it is possible to suppress the necessity of newly adding a process or a material to form the bank structure 130, and it is also possible to enhance the dimensional stability of the bank structure 130.

### 4-3 Modification

### Modification 1

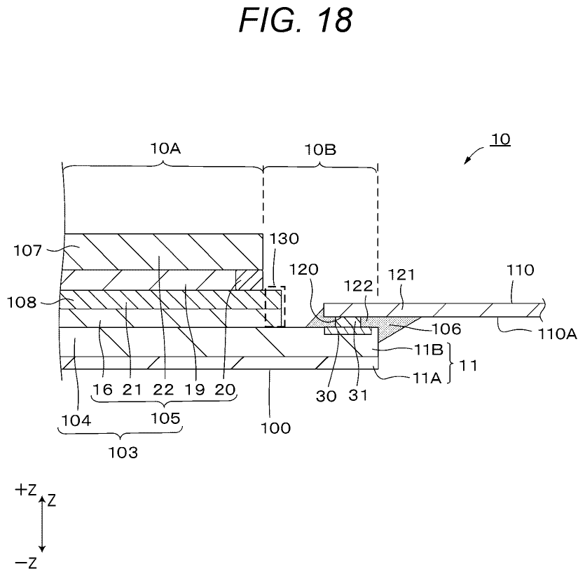

In the display apparatus 10 according to the fourth embodiment, as described in the first embodiment, the covering structure 105 may be provided with the organic functional layer 108 as another layer different from the protective layer 16 and the like described above at least between the protective layer 16 and the surface layer 107. In this case, as illustrated in FIG. 18, in the display apparatus 10 according to the fourth embodiment, the bank structure 130 may have a structure in which at least a part of the protective layer 16 and at least a part of the organic functional layer 108 are laminated. This form is referred to as Modification 1 of the fourth embodiment. FIG. 18 is a cross-sectional view schematically illustrating an example of a display apparatus according to Modification 1 of the fourth embodiment. Note that, in FIG. 18, the connection wiring 114 is omitted for convenience of description. It similarly applies to FIGS. 21A, 21B, 22A, 22B, 23A, and 23B.

### Covering Structure

In the covering structure 105, an organic functional layer 108 different from the above-described protective layer 16 or the like is provided at least between the protective layer 16 and the surface layer 107. In the example of FIG. 18, the covering structure 105 includes a filling resin layer 19 and a sealing layer 20 between the protective layer 16 and the surface layer 107, and an organic functional layer 108 is provided at least between the filling resin layer 19 and the protective layer 16. As described in the first embodiment, the organic functional layer 108 is a layer containing an organic compound, and examples thereof include the planarization layer 21 and a wavelength selective layer (color filter 18 or the like). In the example of FIG. 18, a planarization layer 21 is formed as the organic functional layer 108. Since the planarization layer 21 is similar to that described in the first embodiment, detailed description thereof is omitted.

### Bank Structure

The bank structure 130 has a structure in which at least a part of the protective layer 16 and at least a part of the organic functional layer 108 are laminated. In the example of FIG. 18, in the structure in which the planarization layer 21 as the organic functional layer 108 and the protective layer 16 are laminated, a portion formed in the outer region 10B in plan view of the display apparatus 10 forms the bank structure 130. In FIG. 18, the bank structure 130 is specified as a portion surrounded by a broken line in the laminated structure of the protective layer 16 and the organic functional layer 108. However, FIG. 18 is an example, and the organic functional layer 108 forming a part of the bank structure 130 may be a wavelength selective layer such as a color filter 18. In this case, the structure of the color filter 18 constituting the bank structure 130 is preferably a structure in which filters corresponding to a plurality of color types are laminated.

According to Modification 1 of the fourth embodiment, the wall surface of the outer end 133B of the bank structure 130 is configured by a surface obtained by combining the outer wall surface of the protective layer 16 and the outer wall surface of the organic functional layer 108. Therefore, the height of the outer end 133B of the bank structure 130 tends to be higher than a case where the organic functional layer 108 is not included in the bank structure 130, and it is possible to more effectively suppress the entry of the underfill material into the display region 10A.

Note that, in the example of FIG. 18, the outer wall surface of the organic functional layer 108 and the outer wall surface of the protective layer 16 are substantially aligned, but this is merely an example, and the organic functional layer 108 may extend in a direction away from the display region 10A (outward direction) so as to cover the outer wall surface of the protective layer 16. The entire organic functional layer 108 may be on the upper side of the protective layer 16.

### Modification 2

In the display apparatus 10 according to the fourth embodiment, the sealing layer 20 is formed at a position between the counter substrate 22 and the protective layer 16, but the sealing layer 20 may be omitted as illustrated in FIG. 22A. This form is referred to as Modification 2 of the fourth embodiment. FIG. 22A is a cross-sectional view schematically illustrating an example of a display apparatus according to Modification 2 of the fourth embodiment. In this case, the filling resin layer 19 is formed up to the outer edge of the display region 10A. The other points are similar to those described in the first to fourth embodiments, and thus the detailed description thereof is omitted.

### Modification 3

In the display apparatus 10 according to the fourth embodiment, the surface layer 107 is constituted by the counter substrate 22, but as illustrated in FIG. 23A, the surface layer 107 may be constituted by the overcoat layer 23. This form is referred to as Modification 3 of the fourth embodiment. FIG. 23A is a cross-sectional view schematically illustrating an example of a display apparatus according to Modification 3 of the fourth embodiment. Since the overcoat layer 23 is similar to that described in Modification 4 of the first embodiment, the detailed description thereof is omitted.

### Modification 4

In the display apparatus 10 according to the fourth embodiment, in the layer forming the bank structure 130 such as the protective layer 16, the portion formed in the display region 10A and the portion formed in the outer region 10B are continuous. However, the present invention is not limited thereto, and the portion formed in the display region 10A and the portion formed in the outer region 10B in the layer forming the bank structure 130 may be separated (not illustrated).

### 5 Fifth Embodiment

### 5-1 Configuration

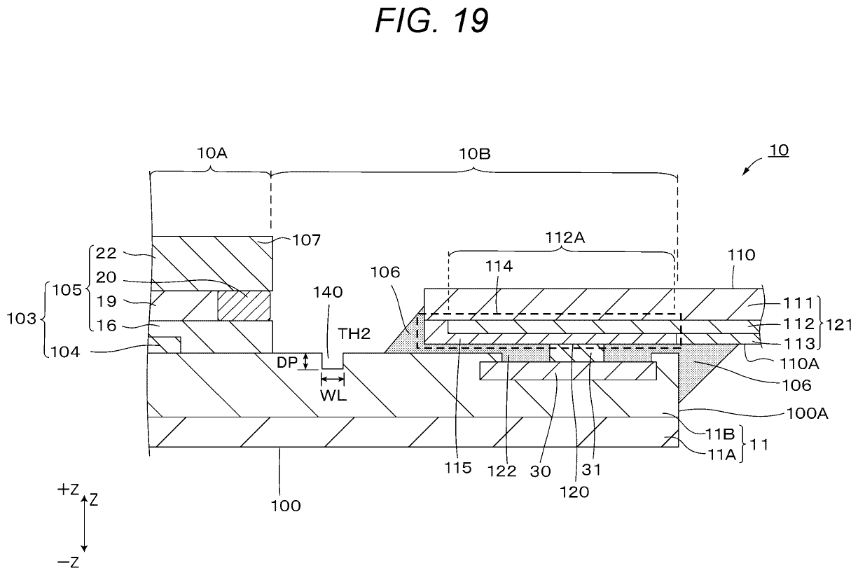

As illustrated in FIG. 19, the display apparatus according to the fifth embodiment has the same configuration as that of the first to fourth embodiments except that a gap 122 between a display panel 100 and a flexible printed circuit 110 is filled with an underfill material (sealing structure 106), and a groove 140 is formed between an external electrode 30 and a display region 10A in the display panel 100. FIG. 19 is a cross-sectional view for explaining an example of a display apparatus according to the fifth embodiment. FIG. 19 illustrates an example of a case where other configurations except the sealing structure 106 and the groove 140 have a configuration similar to that of the first embodiment.

In the example of FIG. 19, the display apparatus 10 according to the fifth embodiment includes a substrate 11A and a covering structure 105 provided on the upper side of the substrate 11A and covering the light emitting element 104. The covering structure 105 includes at least a surface layer 107 and a protective layer 16. In addition, in the example of FIG. 19, the filling resin layer 19 is formed between the surface layer 107 and the protective layer 16, and the sealing layer 20 is formed so as to cover the outer wall surface of the filling resin layer 19. Note that, in the following description of the fifth embodiment, detailed description of configurations similar to those of the first to fourth embodiments, such as the light emitting element 104 and the surface layer 107, will be omitted.

### Groove

As described above, in a case where the thickness direction (Z-axis direction) of the display panel 100 is a line-of-sight direction (in plan view of the display apparatus 10), the groove 140 is formed between the display region 10A and the external electrode 30. The phrase “formed between the display region 10A and the external electrode 30” means that, assuming a straight line connecting the external electrode 30 and the display region 10A, the groove 140 is formed such that the straight line and the groove 140 intersect.

### Planar Shape of Groove

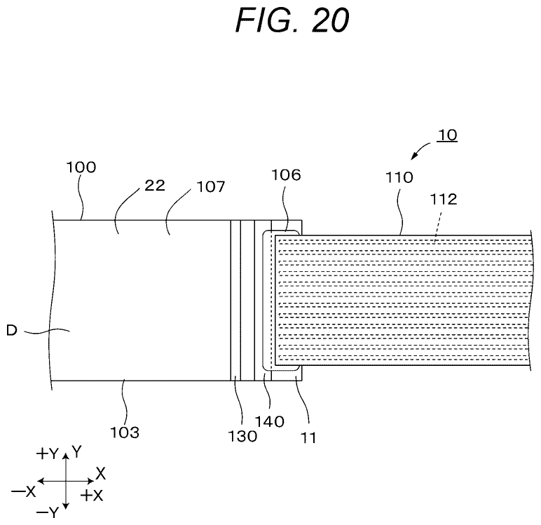

The shape of the groove 140 is not particularly limited in plan view of the display apparatus 10, but for example, the groove 140 may be formed in a linear shape extending along one side of the outer peripheral edge of the display region 10A. More specifically, as illustrated in FIG. 20 and the like, the groove 140 is formed linearly at a position away from the display region 10A by a predetermined distance along one side of the rectangular display region 10A. However, this is an example, and the shape of the groove 140 is not limited to a straight line as described later, and may be a curved line, a polygonal line, or the like.

### Cross-Sectional Shape of Groove

The cross-sectional shape (shape of longitudinal cross section) of the groove 140 is not particularly limited, and may be a non-tapered shape, a tapered shape, or an inversely tapered shape. In the example of FIG. 19, the cross-sectional shape of the groove 140 is a non-tapered shape.

### Dimensions of Groove

Dimensions such as a width (WL in FIG. 19) and a depth (DP in FIG. 19) of the groove 140 are not particularly limited, but it is preferable that a size to such an extent that at least a part of the overflowing underfill material can be received even in a case where the underfill material overflows from the gap 122 to the display region 10A side is secured. From this point of view, for example, the width (WL) of the groove 140 may be approximately 5 μm, and the depth (DP) of the groove may be approximately 1 μm.

### Position of Groove

The position of the groove 140 is not particularly limited as long as it is a position between the external electrode 30 and the display region 10A.

### Sealing Structure

Also in the display apparatus 10 according to the fifth embodiment, similarly to the case described in the fourth embodiment, the sealing auxiliary layer 123 may be formed in the sealing structure 106 as illustrated in FIG. 21B. FIG. 21B is a cross-sectional view for explaining an example in a case where the display apparatus 10 according to the fifth embodiment includes the sealing auxiliary layer 123.

The display apparatus according to the fifth embodiment may be combined with the fourth embodiment as illustrated in FIG. 20. In this case, the display apparatus according to the fifth embodiment includes a groove 140 and a bank structure 130. FIG. 20 is a plan view for explaining an example in a case where the display apparatus 10 according to the fifth embodiment has a bank structure 130.

### 5-2 Manufacturing Method

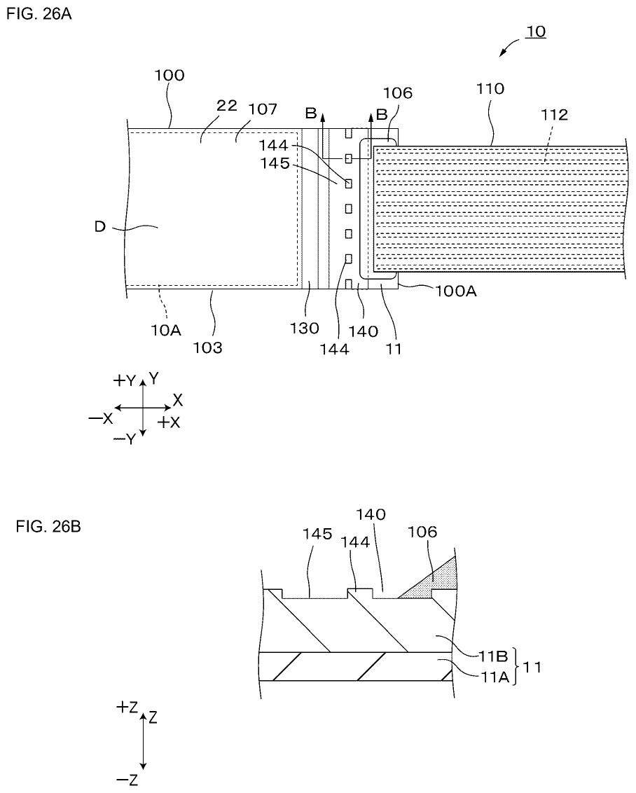

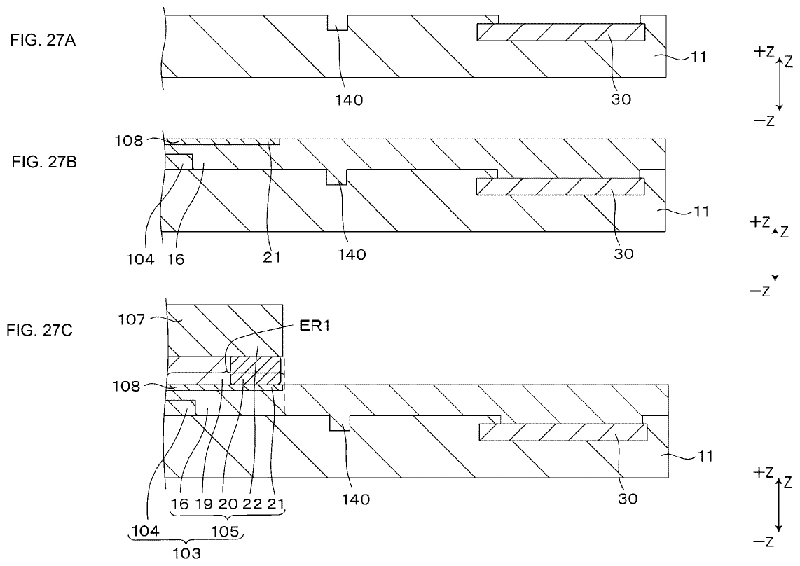

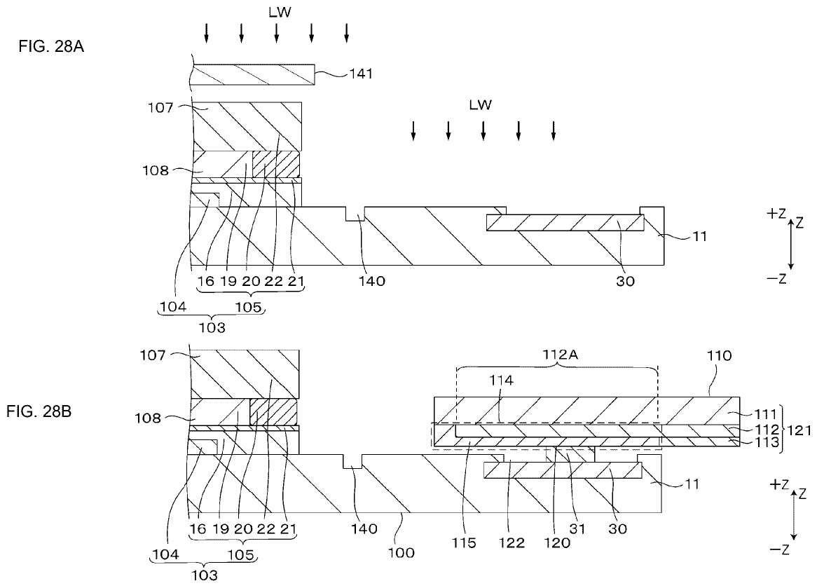

A method for manufacturing the display apparatus 10 according to the fifth embodiment will be described with reference to FIGS. 27A, 27B, 27C, 28A, and 28B. FIGS. 27A, 27B, 27C, 28A, and 28B are cross-sectional views for explaining the method for manufacturing the display apparatus 10 according to the fifth embodiment. Note that, in FIGS. 27A to 27C and FIGS. 28A and 28B, for convenience of description, description of the inorganic insulating layer 11B and description of various circuits on the substrate 11A are omitted, and description of each layer constituting the light emitting element 104 is omitted.

The inorganic insulating layer 11B and various circuits are formed on the substrate 11A. At this time, an electrode constituting the external electrode 30 is also formed. Next, the external electrode 30 is exposed using an etching method or the like. At this time, as illustrated in FIG. 27A, the groove 140 is formed in accordance with the exposure of the external electrode 30. As a result, a structure in which the groove 140 is formed in the drive substrate 11 is formed. Next, as illustrated in FIG. 27B, various layers (organic layers and the like) constituting the light emitting element 104 are formed on the first surface of the drive substrate 11, and the protective layer 16 is further formed on the entire first surface. In addition, various organic functional layers 108 are formed as necessary. In the example of FIG. 27B, a planarization layer 21 is formed as the organic functional layer 108. Note that the various layers constituting the light emitting element 104, the protective layer 16, and the organic functional layer 108 can be specifically formed, for example, by appropriately using a conventional method. Furthermore, as illustrated in FIG. 27C, a counter substrate 22 that forms the filling resin layer 19 and the sealing layer 20 and becomes the surface layer 107 is provided.

As illustrated in FIG. 28A, in the protective layer 16, a portion ER1 corresponding to the display region 10A is left, and the other portion is removed. At this time, the groove 140 and the external electrode 30 are exposed. Note that, in a case where the bank structure 130 is formed in the display apparatus 10, a portion of the protective layer 16 corresponding to the bank structure 130 is also left. As a method of removing the protective layer 16, for example, a photolithography method or the like can be used. Note that, in FIG. 28A, reference sign 141 denotes a photomask. An arrow LW indicates an exposure direction at the time of mask exposure in the photolithography method.

Further, as illustrated in FIG. 28B, a bump electrode 31 is provided on the upper surface of the external electrode 30. As a method for forming the bump electrode 31, a method corresponding to the configuration of the bump electrode 31 is adopted. For example, in a case where the bump electrode 31 is a stud bump as in the bump electrode 31 described in the first embodiment, the bump electrode 31 may be formed by a wire bonding method. Then, the connection wiring 114 of the flexible printed circuit 110 and the bump electrode 31 are bonded. As the bonding method, an ultrasonic bonding method is preferably used as illustrated in the first embodiment and the like.

Then, an underfill material is injected into the gap 122 between the flexible printed circuit 110 and the display panel 100 to cure the underfill material. As a result, the sealing structure 106 is formed, and for example, the display apparatus 10 as illustrated in FIG. 19 is manufactured.

Note that, when the photolithography method is applied using the photomask 141, in a case where the portion ER1 corresponding to the display region 10A and the above-described portion ER2 are left in the protective layer 16, the bank structure 130 can be formed.

### 5-3 Operation and Effects

According to the display apparatus 10 of the fifth embodiment, since the groove 140 is formed between the display region 10A and the external electrode 30, it is possible to extend the moving distance required for the underfill material to reach the display region 10A. In addition, trapping the underfill material traveling toward the display region 10A in the internal space of the groove 140 makes it easy to block the underfill material. Therefore, according to the display apparatus 10 according to the fifth embodiment, similarly to the fourth embodiment, it is possible to effectively reduce the possibility that the underfill material overflowing to the outside from the gap 122 between the flexible printed circuit 110 and the display panel 100 enters the display region 10A side.

According to the display apparatus 10 according to the fifth embodiment, since the groove 140 can be formed in accordance with the processing for exposing the external electrode 30 formed in the inorganic insulating layer 11B, it is possible to suppress the necessity of newly adding a process or a material for forming the groove 140, and it is also possible to enhance the dimensional stability of the groove 140.

### 5-4 Modification

### Modification 1

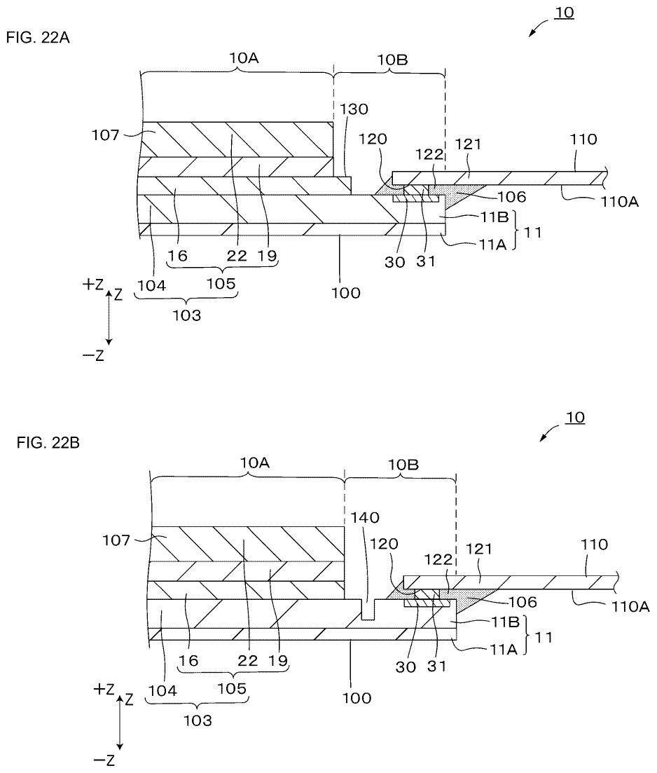

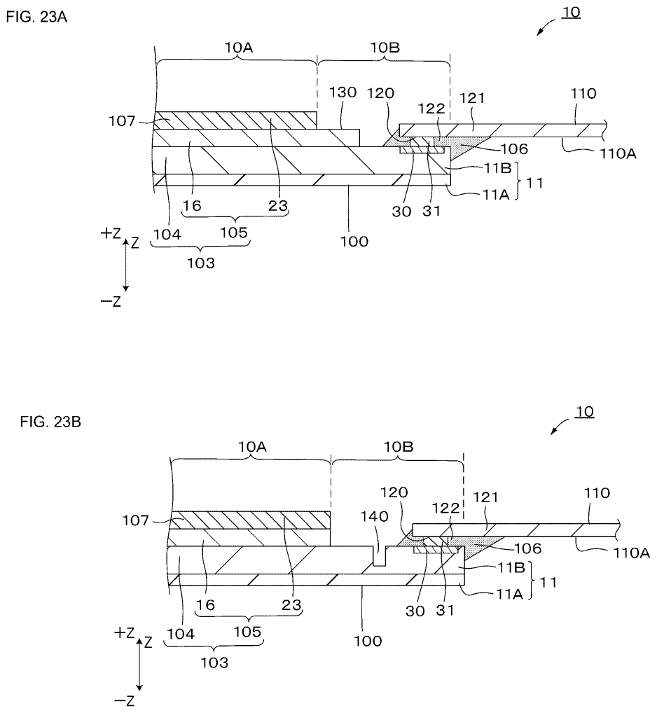

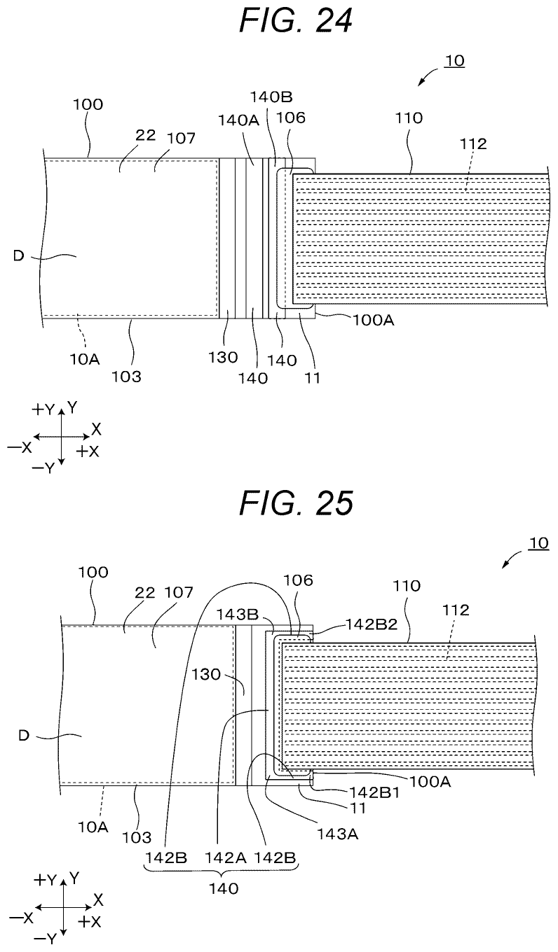

In the display apparatus 10 according to the fifth embodiment, as illustrated in FIG. 24, a plurality of grooves 140 may be provided. This form is referred to as Modification 1 of the fifth embodiment. FIG. 24 is a plan view schematically illustrating an example of a display apparatus according to Modification 1 of the fifth embodiment. Note that FIG. 24 illustrates an example in a case where the display apparatus 10 forms the groove 140 and the bank structure 130, but the bank structure 130 may be omitted.

### Groove

In the display apparatus 10 according to Modification 1 of the fifth embodiment, the grooves 140 are formed at a plurality of places, and in the example of FIG. 24, two grooves 140 are provided. The shape of each groove 140 is not particularly limited. In a case where the grooves 140 are the grooves 140A and the grooves 140B, the shapes of the grooves 140A and 140B may be determined independently. In the example of FIG. 24, the two grooves 140A and 140B are provided so as to be parallel to each other, but this is an example. The grooves 140A and 140B are each disposed between the display region 10A and the external electrode 30. In addition, in the example of FIG. 24, a part of the underfill material flows into the groove 140B located relatively outside, and the groove 140B, in particular, of the two grooves 140A and 140B, suppresses the entry of the underfill material into the display region 10A.

### Modification 2

In the display apparatus 10 according to the fifth embodiment, as illustrated in FIG. 25, the groove 140 may have a first portion and a second portion different in the longitudinal direction. This form is referred to as Modification 2 of the fifth embodiment. FIG. 25 is a plan view schematically illustrating an example of a display apparatus according to Modification 2 of the fifth embodiment.

### Groove

In the display apparatus according to Modification 2 of the fifth embodiment, the groove 140 includes a first portion 142A formed in a linear shape along one side of the outer edge of the display region 10A and a second portion 142B extending outward from the end portions (the first end portion 143A and the second end portion 143B) of the first portion 142A. As the second portion 142B, two portions of a portion 142B1 extending outward from the first end portion 143A and a portion 142B2 extending outward from the second end portion 143B are formed.

In the display apparatus 10 according to Modification 2 of the fifth embodiment, the groove 140 is formed such that all the external electrodes 30 are arranged inside the rectangular region formed by the groove 140 and the outer end 100A of the display panel 100.

### Modification 3

In the display apparatus 10 according to the fifth embodiment, as illustrated in FIG. 26, a protruding structure 144 may be provided inside the groove 140 in plan view of the display apparatus 10. This form is referred to as Modification 3 of the fifth embodiment. FIG. 26 is a plan view schematically illustrating an example of a display apparatus 10 according to Modification 3 of the fifth embodiment.

### Groove

In the display apparatus according to Modification 2 of the fifth embodiment, a plurality of protruding structures 144 protruding upward from the bottom surface 145 of the groove 140 is formed inside the groove 140. Regarding the layout of the groove 140, in the example of FIG. 26, the plurality of protruding structures 144 is arranged in a line at intervals along the longitudinal direction of the groove 140, but the layout of the protruding structure 144 illustrated here is an example. The layout of the protruding structures 144 is not particularly limited, and may be staggered or arranged in a grid pattern. In addition, the shape of the protruding structure 144 illustrated in the example of FIG. 26 is a rectangular shape in a plan view of the display apparatus 10, but this is an example of the protruding structure 144. The shape of the protruding structure 144 is not particularly limited, and may be a circular shape, an elliptical shape, or the like in a plan view of the display apparatus 10. In addition, the shapes of the plurality of protruding structures 144 may be the same as each other, or the shapes of at least some of the protruding structures 144 may be different from the shapes of the other protruding structures 144.

According to the display apparatus 10 according to Modification 3 of the fifth embodiment, when a part of the underfill material flows into the groove 140B due to the formation of the protruding structure 144, and the underfill material comes into contact with the protruding structure 144, it is considered that the flow of the underfill material toward the display region 10A can be suppressed.

### Modification 4

In the display apparatus 10 according to the fifth embodiment, the sealing layer 20 is formed at a position between the counter substrate 22 and the protective layer 16, but the sealing layer 20 may be omitted as illustrated in FIG. 22B. This form is referred to as Modification 4 of the fifth embodiment. FIG. 22B is a cross-sectional view schematically illustrating an example of a display apparatus according to Modification 4 of the fifth embodiment. In this case, as described in Modification 2 of the fourth embodiment, the filling resin layer 19 is formed up to the outer edge of the display region 10A. The other points are similar to those described in the first to fourth embodiments, and thus the detailed description thereof is omitted.

### Modification 5

In the display apparatus 10 according to the fifth embodiment, the surface layer 107 is constituted by the counter substrate 22, but as illustrated in FIG. 23B, the surface layer 107 may be constituted by the overcoat layer 23 in a similar manner described in the fourth embodiment also in the display apparatus according to the fifth embodiment. This form is referred to as Modification 5 of the fifth embodiment. FIG. 23B is a cross-sectional view schematically illustrating an example of a display apparatus according to Modification 5 of the fifth embodiment. Since the overcoat layer 23 is similar to that described in Modification 4 of the first embodiment, the detailed description thereof is omitted.

### 6 Sixth Embodiment

### 6-1 Configuration

A display apparatus 10 according to the sixth embodiment has the same configuration as that of the first to fifth embodiments except that a circuit structure 200 different from a flexible printed circuit 110 is mounted on an upper side of a substrate 11A of a display panel 100 between a bump electrode 31 and a display region 10A in plan view of a display apparatus 10.

An example of the sixth embodiment will be described in order of the first example and the second example. Note that, in the following description of the sixth embodiment, the description of a configurations similar to those of the first to fifth embodiments will be omitted.

### First Example

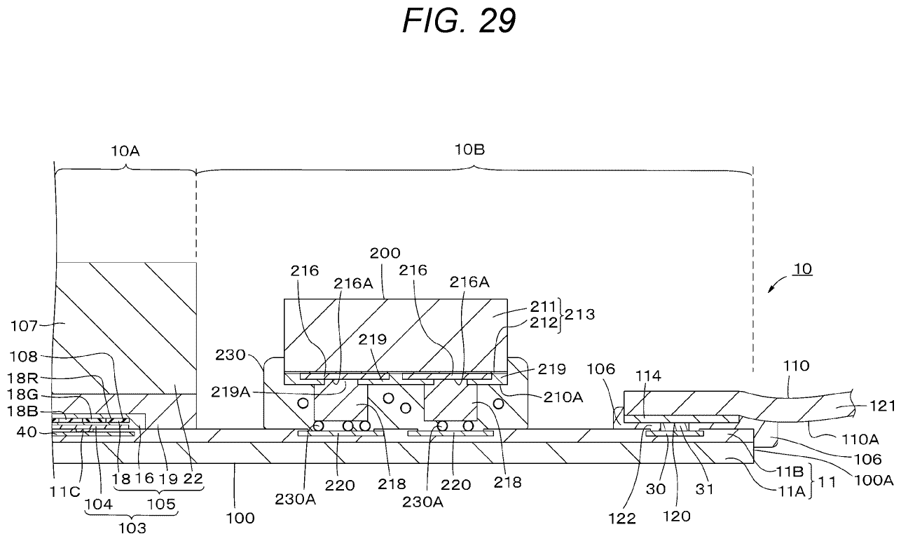

As illustrated in FIG. 29, in a display apparatus 10 according to a first example of the sixth embodiment, in the display apparatus according to any one of the first to third embodiments, a circuit structure 200 is provided between an external electrode 30 and a display region 10A in plan view of the display apparatus 10. FIG. 29 is a cross-sectional view for explaining an example of a display apparatus according to a first example of the sixth embodiment. In the example of the sixth embodiment illustrated in FIG. 29, an example in a case where the circuit structure 200 is provided in the display apparatus according to the first embodiment is illustrated.

In the display apparatus 10 according to the first example of the sixth embodiment, the configuration of the display structure 103 is similar to that of the first embodiment to the third embodiment, and thus, in FIG. 29, the layer configuration of the display structure 103 is illustrated by omitting the detailed configuration of the circuit 40 formed in the inorganic insulating layer 11B, a part of the configuration of the contact plug 11C, and the like for convenience of description. In addition, a detailed layer configuration of the light emitting element 104 electrically connected to the contact plug 11C is omitted. In addition, detailed description of the protective layer 16, the planarization layer 21, and the like in the covering structure 105 is also omitted.

### Circuit Structure

The circuit structure 200 is not particularly limited as long as it is a circuit board that can be installed at a position between the bump electrode 31 and the display region 10A. Specifically, a display driver integrated circuit (IC) ; DDIC) can be exemplified as the circuit structure 200. In the example of FIG. 29, the DDIC as the circuit structure 200 is disposed between the external electrode 30 and the display region 10A, and the DDIC as the circuit structure 200 and the display panel 100 are electrically connected to each other.

In the example of FIG. 29, the circuit structure 200 includes a substrate 213 having a structure in which a drive circuit layer 212 is formed on a base substrate 211. Similarly to the substrate 211, a glass substrate, a semiconductor substrate, a resin substrate, or the like may be used as the base substrate 11A. As the base substrate 211, a silicon substrate or the like can be suitably used.

The substrate 213 is provided with an electrode pad 216 on the opposing surface 210A side with respect to the display panel 100. The structure of the electrode pad 216 is not particularly limited, and a metal layer constituted by a metal material such as aluminum can be exemplified. In the example of FIG. 29, in the display panel 100, an electrode pad 220 electrically connected to the circuit structure 200 is provided on the first surface of the drive substrate 11. The electrode pad 220 and the electrode pad 216 are provided so as to face each other when the circuit structure 200 is disposed on the display panel 100. Note that the number of electrode pads 220 and electrode pads 216 formed is not particularly limited.

### Bump Electrode

The bump electrode 218 is disposed between the drive substrate 11 and the circuit structure 200. As the bump electrode 218, a so-called bump is suitably used. In the example of FIG. 29, the bump electrode 218 is provided on the electrode pad 216. That is, in the circuit structure 200, the bump electrode 218 is provided on a predetermined region including the exposed surface 216A of the electrode pad 216, and the circuit structure 200 is electrically connected to the electrode pad 216. The bump electrode 218 is preferably a structure formed by a method selected from electrolytic plating, electroless plating, and a stud bump forming method. However, this does not exclude that the bump electrode 218 is formed by a method other than these methods.

Examples of the material of the bump electrode 218 include gold, silver, copper, and aluminum.

### Insulating Layer

An insulating layer 219 is provided on the opposing surface 210A side of the circuit structure 200. The insulating layer 219 fills a space between the adjacent electrode pads 216 in plan view of the circuit structure 200. Furthermore, as illustrated in FIG. 29, the insulating layer 219 may be formed so as to ride on the surface (second surface) of the electrode pad 216 so as to cover the outer peripheral edge of the electrode pad 216. However, an opening 219A is formed in the insulating layer 219, and the electrode pad 216 is exposed from the opening 219A. A surface portion of the electrode pad 216 exposed from the opening 219A is an exposed surface 216A.

### Method of Connecting Circuit Structure and Drive Substrate

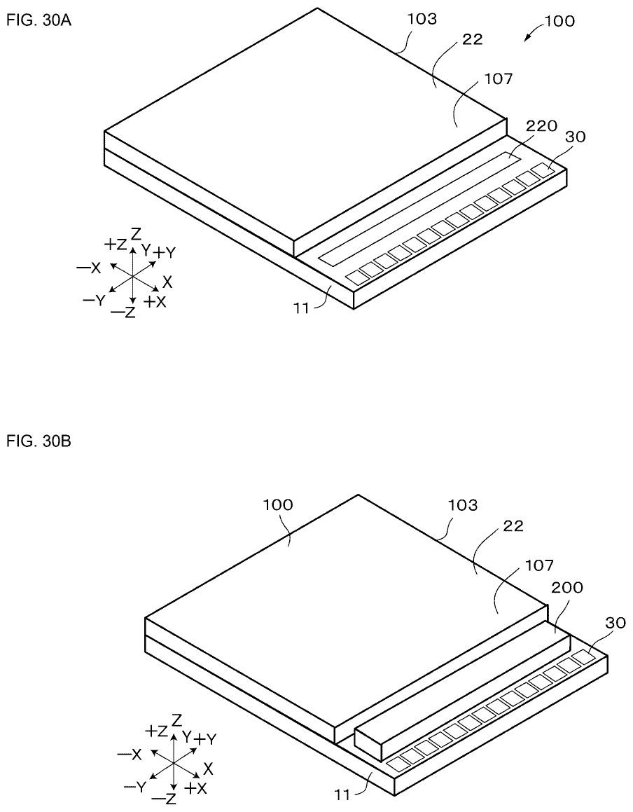

The circuit structure 200 is electrically connected to various circuits of the drive substrate 11. A method of connecting the drive substrate 11 and the circuit structure 200 is not particularly limited. As this connection method, for example, a method using an anisotropic conductive film (ACF) 230, which is constituted by a resin film containing conductive particles 230A, as illustrated in FIG. 29, can be cited. This method can be realized by, for example, chip on chip (COC) implementation using a pressure bonding process. First, as illustrated in FIG. 30A, the display panel 100 is prepared. Then, the circuit structure 200 and the display panel 100 are aligned such that the bump electrode 218 of the circuit structure 200 faces the electrode pad 220 on the drive substrate 11 side via the anisotropic conductive film 230. Then, the circuit structure 200 is pressed against the display panel 100, and as illustrated in FIG. 30B, the bump electrode 218 and the electrode pad 220 are pressure-bonded via the anisotropic conductive film 230. At the time of pressure bonding, the circuit of the drive substrate 11 and the circuit of the circuit structure 200 are electrically connected via the conductive particles 230A contained in the anisotropic conductive film 230. Note that, at this time, the formation surface (active surface) of the drive circuit layer 212 of the circuit structure 200 faces the drive substrate 11 side, and the circuit structure 200 is flip-chip mounted on the drive substrate 11. Note that, in FIG. 30A, detailed description of the electrode pad 220 is omitted for convenience of description.

### Connection Between Display Panel and Flexible Printed Circuit

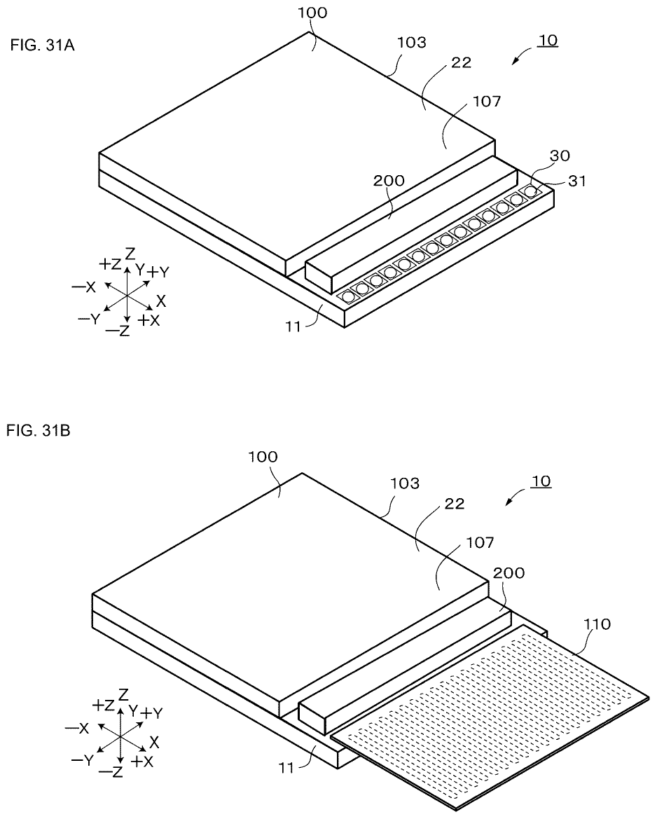

The flexible printed circuit 110 is electrically connected to the display panel 100 on which the circuit structure 200 is mounted. For example, as described in the first embodiment and the like, as illustrated in FIG. 31A, the bump electrode 31 is provided on the external electrode 30 of the display panel 100, the head 150 that attracts the flexible printed circuit 110 is disposed at a predetermined position of the display panel 100, and the bump electrode 31 and the connection wiring 114 are metal-bonded to each other by ultrasonic bonding. Ultrasonic bonding can be realized, for example, by moving the flexible printed circuit 110 and/or the display panel 100 in the vertical direction and applying an ultrasonic wave in a plane direction whose normal direction is the vertical direction while bringing the bump electrode 31 and the connection wiring 114 into contact with each other. Note that, as a method of forming the bump electrode 31, a method according to the structure of the bump electrode 31, such as a wire bonding method, is selected. Note that, in FIGS. 31B and 31C, description of a detailed layer configuration of the flexible printed circuit 110 such as description of the connection wiring 114 is omitted for convenience of description. After the bump electrode 31 and the connection wiring 114 are metal-bonded, the gap 122 is filled with an underfill material as necessary. Thus, as illustrated in FIG. 31B, a structure in which the circuit structure 200 and the flexible printed circuit 110 are connected to the drive substrate 11 of the display panel 100 is obtained.

### Second Example

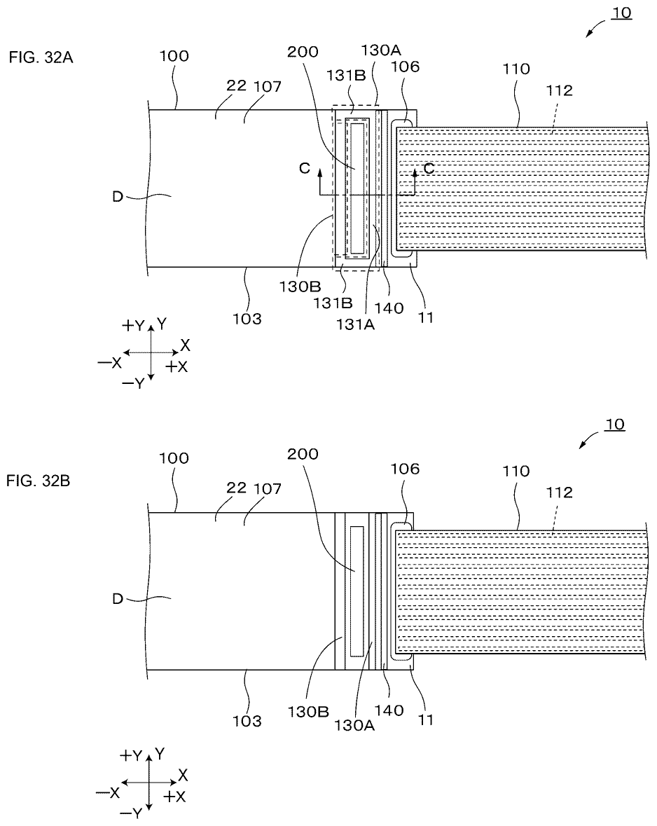

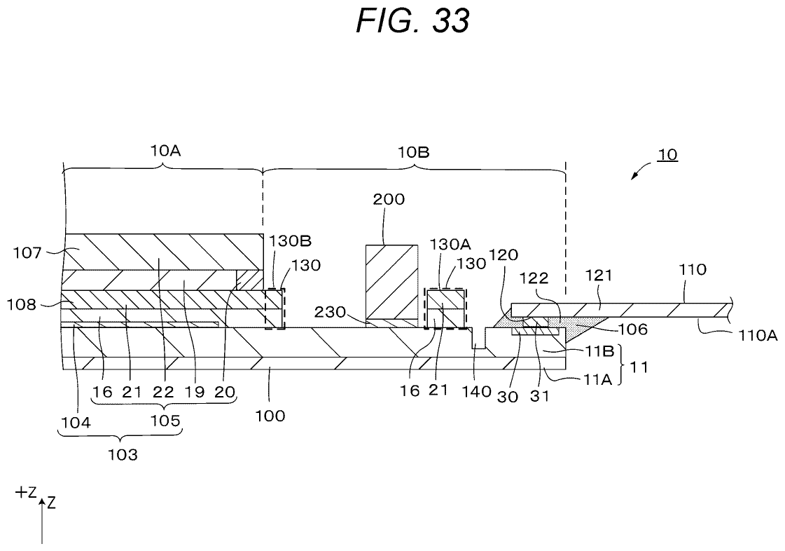

As illustrated in FIGS. 32A and 33, in a display apparatus 10 according to a second example of the sixth embodiment, in the display apparatus according to the fourth embodiment and/or the fifth embodiment, a circuit structure 200 is provided between an external electrode 30 and a display region 10A in plan view of the display apparatus 10. FIGS. 32A and 33 are a plan view and a cross-sectional view for explaining an example of a display apparatus according to a second example of the sixth embodiment. In the example of the sixth embodiment illustrated in FIGS. 32A and 33, an example in which a circuit structure 200 is provided in a display apparatus obtained by combining the fourth embodiment and the fifth embodiment is illustrated. In FIGS. 32A, 33, and the like, detailed description of the configuration of the circuit structure 200, the electrode pad 220 formed on the display panel 100 side, and the configuration of the flexible printed circuit 110 is omitted for convenience of description. It similarly applies to FIG. 32B in that the detailed description as described above is omitted. The configuration of the circuit structure 200 and the method of connecting the circuit structure 200 and the drive substrate 11 of the display panel 100 are similar to those in the first example described above, and thus detailed description is omitted. In addition, the configuration of the flexible printed circuit 110 and the method of connecting the flexible printed circuit 110 and the display panel 100 are similar to those in the first example described above, the first embodiment described above, and the like, and therefore, the detailed description is omitted.

In addition, in the display apparatus 10 according to the second example of the sixth embodiment, the configuration of the display structure 103 is similar to that of the above-described first example. In FIGS. 32A and 33, the detailed layer configuration of the drive substrate 11 and the detailed layer configuration of the light emitting element 104 are omitted for convenience of description with respect to the layer configuration of the display structure 103. In FIG. 33, a protective layer 16, a planarization layer 21, a filling resin layer 19, a sealing layer 20, and a counter substrate 22 are illustrated for layers constituting the covering structure 105. Since the layers constituting the drive substrate 11, the light emitting element 104, and the covering structure 105 are similar to those described in the first to fifth embodiments, detailed description thereof is omitted.

In the display apparatus 10 according to the second example of the sixth embodiment, as illustrated in FIGS. 32A and 33, the groove 140 and the circuit structure 200 are provided between the external electrode 30 and the display region 10A in a plan view of the display apparatus 10. In addition, the display apparatus 10 according to the second example of the sixth embodiment includes the bank structure 130.

### Groove

The groove 140 is formed outside the circuit structure 200 (between the circuit structure 200 and the external electrode 30). In the example of FIG. 32, the groove 140 is formed outside the bank structure 130 (between the first bank structure 130A and the external electrode 30).

### Bank Structure

The bank structure 130 is constituted by a layer forming the covering structure 105, and has a structure in which the protective layer 16 and the planarization layer 21 are laminated in the example of FIG. 33. In FIG. 33, the bank structure 130 is specified as a portion surrounded by a broken line. In addition, in the example of FIG. 33, as the bank structure 130, a first bank structure 130A which is a structure forming a step portion formed outside the circuit structure 200 and a second bank structure 130B which is a structure forming a step portion inside the circuit structure 200 are formed. The first bank structure 130A has a front end portion 131A and a side end portion 131B. The front end portion 131A is a portion that partitions the inside of the outer region 10B between the display region 10A and the external electrode 30 (inside the outer region 10B) and outside the circuit structure 200, and forms a step and a wall surface. The side end portion 131B is specified as a portion extending from both ends separated in the longitudinal direction of the front end portion 131A toward the display region 10A side, and is a portion continuous with the protective layer 16 and the planarization layer 21 formed in the display region 10A in the covering structure 105.

The second bank structure 130B has a structure obtained by extending the protective layer 16 and the planarization layer 21 formed in the display region 10A of the covering structure 105. In the example of FIG. 32A, the first bank structure 130A and the second bank structure 130B are continuous to the second bank structure 130B at the side end portion 131B of the first bank structure 130A. This can be realized by forming a structure in which the protective layer 16 and the planarization layer 21 are laminated in a shape surrounding the circuit structure 200 in plan view of the display apparatus 10 when the bank structure 130 is formed.

Note that the example illustrated in FIG. 32A is an example, and as illustrated in FIG. 32B, the first bank structure 130A and the second bank structure 130B may be separated. FIG. 32B is a plan view for explaining another example of the display apparatus 10 according to the second example of the sixth embodiment.

In the second example described above, both the groove 140 and the bank structure 130 are formed, but only one of them may be formed. In addition, in the bank structure 130, the first bank structure 130A and the second bank structure 130B are formed, but only one of them may be formed.

### 6-2 Operation and Effects

According to the display apparatus according to the sixth embodiment, effects similar to those of the first embodiment can be obtained in both the first example and the second example.

According to the display apparatus according to the second example of the sixth embodiment, it is possible to obtain an effect similar to the effects of the fifth embodiment and the fourth embodiment in addition to the effect similar to the effect of the first embodiment.

In the display apparatus described in the examples of the first to sixth embodiments described above, the first structure SB1 is the external electrode 30 of the display panel 100, and the second structure SB2 is the connection wiring 114 of the flexible printed circuit 110. In the display apparatus 10, as in a seventh embodiment described below, the first structure SB1 may be the connection wiring 114 of the flexible printed circuit 110, and the second structure SB2 may be the external electrode 30 of the display panel 100.

### 7 Seventh Embodiment

### 7-1 Configuration

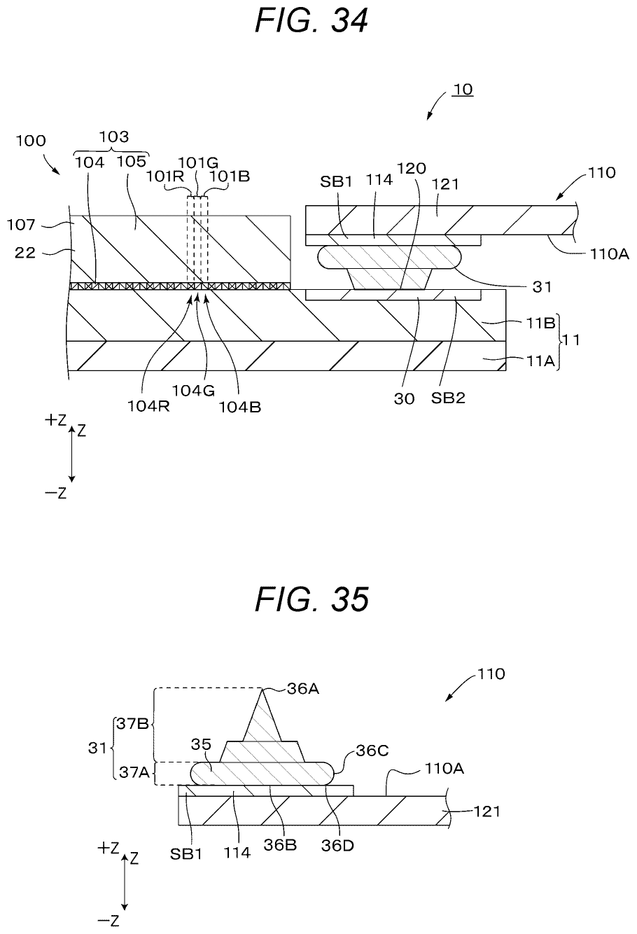

In the display apparatus 10 according to the seventh embodiment, as described above, the first structure SB1 is used as the connection wiring 114 of the flexible printed circuit 110, and the second structure SB2 is used as the external electrode 30 of the display panel 100. Then, as illustrated in FIG. 34, the bump electrode 31 is provided with the connection wiring 114 to be the first structure SB1, and is metal-bonded to the external electrode 30 to be the second structure SB2. As illustrated in FIG. 34, the display apparatus 10 according to the seventh embodiment has the same configuration as the configuration illustrated in any one of the first to sixth embodiments except for the points of the first structure SB1 and the second structure SB2. FIG. 34 is a schematic cross-sectional view for explaining an example of the display apparatus according to the seventh embodiment. In the example of FIG. 34, an example of a case where the display apparatus 10 according to the seventh embodiment has a configuration similar to the display apparatus according to the first embodiment with respect to other configurations except for the first structure SB1 and the second structure SB2 is illustrated.

Note that, in the following description of the seventh embodiment, the description of a configuration similar to that illustrated in any of the first to sixth embodiments will be omitted.

### Display Panel and Flexible Printed Circuit

The display panel 100 is configured similarly to the display panel described in any one of the first to sixth embodiments except that the bump electrode 31 is omitted from the external electrode 30. The flexible printed circuit 110 may be configured similarly to the flexible printed circuit illustrated in any one of the first to sixth embodiments except that the bump electrode 31 is provided on the connection wiring 114.

### Bump Electrode

With respect to the other configuration in which the portion where the bump electrode 31 is installed is the connection wiring 114 of the flexible printed circuit 110 and the portion where the bump electrode 31 is metal-bonded is the external electrode 30, the bump electrode 31 is configured similarly to the bump electrode described in any one of the first to sixth embodiments.

A stud bump may be adopted as the bump electrode 31 illustrated in FIG. 34. As described in the first embodiment, the stud bump can be formed on the connection wiring 114 by using a metal wire such as a gold wire corresponding to the material of the bump electrode 31 and a wire bonding technique.

### Bonding of Display Panel and Flexible Printed Circuit

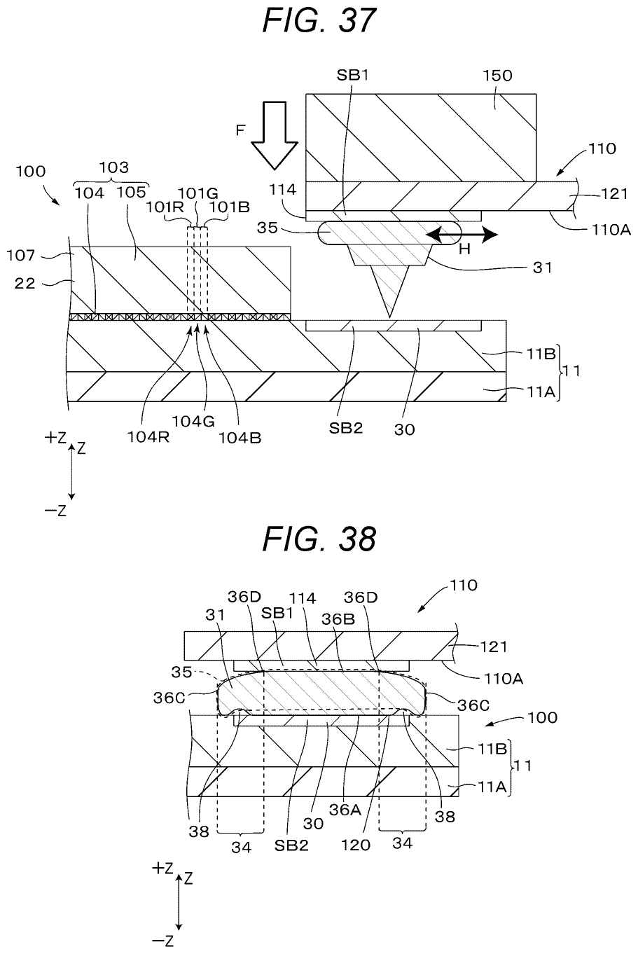

In the display apparatus 10, the flexible printed circuit 110 is disposed on the display panel 100 with the connection wiring 114 facing the first surface side (in FIG. 34, the surface side on the +Z direction side) of the outer region 10B such that the connection wiring 114 is positioned on the outer region 10B. In addition, the individual connection wirings 114 of the flexible printed circuit 110 and the individual external electrodes 30 face each other, and the bump electrode 31 is disposed between the connection wirings 114 and the external electrodes 30. However, in the seventh embodiment, as also illustrated in FIG. 37 and the like, unlike the first embodiment, the base end 36B side of the bump electrode 31 is in contact with the front surface side of the connection wiring 114, and the projecting end side (distal end 36A side) of the bump electrode 31 is directed to the external electrode 30. In the display apparatus 10, the bump electrode 31 provided on the connection wiring 114 of the flexible printed circuit 110 is metal-bonded to the external electrode 30 of the display panel 100. Note that metal bonding indicates that metals are directly bonded to each other as illustrated in the first embodiment. The flexible printed circuit 110 and the display panel 100 (for example, the light emitting element 104, various circuits, and the like) are electrically connected to each other by metal bonding. Note that a portion where the bump electrode 31 of the display panel 100 and the second structure SB2 are metal-bonded to each other is referred to as the metal bonding portion 120. In the seventh embodiment, the bump electrode 31 and the external electrode 30 are metal-bonded to form the metal bonding portion 120.

### Ultrasonic Bonding

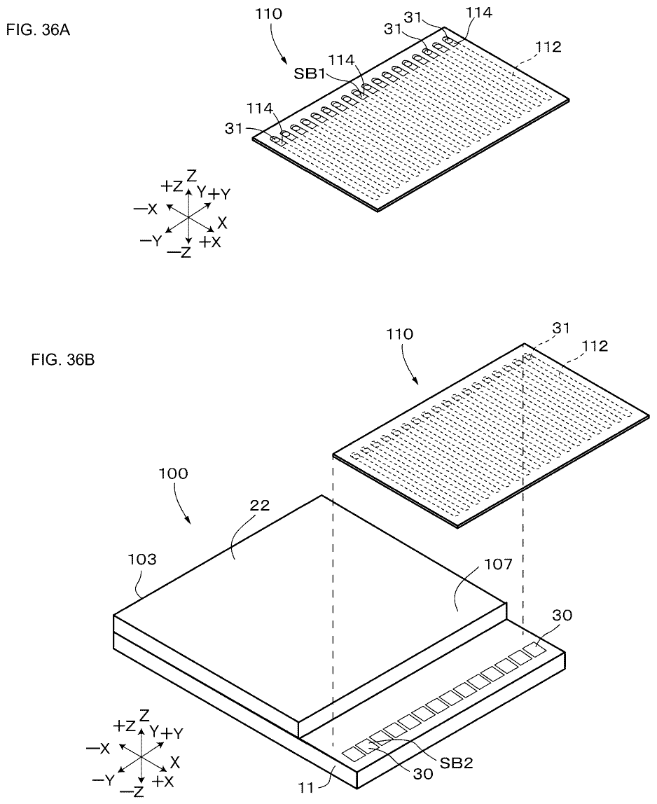

As described in the first embodiment, the metal bonding portion 120 can be formed by, for example, ultrasonic bonding. An example of ultrasonic bonding will be specifically described. As illustrated in FIGS. 35 and 36A, the flexible printed circuit 110 on which the display panel 100 and the bump electrode 31 are formed is prepared. As illustrated in FIG. 37, the flexible printed circuit 110 is attracted and held by the head 150, and as illustrated in FIG. 36B, the formation surface of the connection wiring 114 of the flexible printed circuit 110 is arranged so as to be oriented to a predetermined position of the outer region 10B of the display panel 100, and the external electrode 30 of the display panel 100 and the connection wiring 114 of the flexible printed circuit 110 are aligned. At this time, alignment is performed such that the bump electrode 31 is positioned between the external electrode 30 and the connection wiring 114. Then, as illustrated in FIG. 37, the head 150 pressurizes the opposing portion approximately between the bump electrode 31 and the external electrode 30 in the direction of arrow F, and applies an ultrasonic wave approximately toward the opposing portion. The ultrasonic wave preferably generates vibration in a plane direction of the flexible printed circuit 110 (vibration in an arrow H direction). At this time, in the seventh embodiment, the bump electrode 31 and the external electrode 30 are bonded by solid-phase diffusion.

### Specification of Metal Bonding Portion

In the method for manufacturing the display apparatus 10 according to the above-described seventh embodiment, the first structure SB1 and the second structure SB2 can be specified by observing the structure of the cut surface of the bump electrode 31. As illustrated in FIG. 38, a state is assumed in which the bump electrode 31 is cut in the longitudinal direction (in the Z-axis direction in the example of FIG. 38) so as to pass through the portion where the metal bonding portion 120 is formed. In addition, a direction from the first structure SB1 toward the second structure SB2 (−Z direction in the example of FIG. 38) is defined as a downward direction. At this time, since the outer end portion 34 of the bump electrode 31 has a shape extending obliquely downward, it is confirmed that the first structure SB1 is the connection wiring 114 and the second structure SB2 is the external electrode 30, and that the metal bonding portion 120 is formed by metal bonding between the external electrode 30 and the bump electrode 31. Note that, in the example of FIG. 38, the gap 38 is formed between the outer end portion 34 and display panel 100. FIG. 38 is a diagram illustrating an example of a shape of the bump electrode 31 in a state where the metal bonding portion 120 is formed by ultrasonic bonding.

The outer end portion 34 of the bump electrode 31 includes the base end 36B, and in a case where a portion defined as a predetermined portion on the base end 36B side with respect to the distal end 36A is defined as the pedestal portion 35, a predetermined position toward the inside of the bump electrode 31 is defined as a reference position in plan view of the bump electrode 31, and is defined as a portion from the reference position to the outer peripheral end of the pedestal portion 35 (the outer peripheral end 36C of the bump electrode 31). In the example of FIG. 38, the outer end portion 34 of the bump electrode 31 is specified as a portion of the bump electrode 31 from the contact end 36D to the outer end (outer peripheral end 36C) with the contact end 36D with the connection wiring 114 as a reference position in a plan view of the bump electrode 31 (a portion of the bump electrode 31 divided by broken lines extending in two vertical directions in FIG. 38).

Further, for example, as illustrated in FIG. 35, in a case where the bump electrode 31 has a shape in which a portion (first portion 37A) in contact with the first structure SB1 and a portion (second portion 37B) extending from the surface of the first portion 37A are integrally formed in a state before the formation of the metal bonding portion 120 (in a state of being provided on the surface of the first structure SB1), the pedestal portion 35 can be defined as a portion corresponding to the first portion 37A.

Note that, in the drawings (FIG. 34 and the like) illustrating a case where the metal bonding portion 120 is formed by ultrasonic bonding among the drawings other than FIG. 38, the shape of the bump electrode 31 does not coincide with the shape of the bump electrode 31 illustrated in the example of FIG. 38 for convenience of description.

The fact that the first structure SB1 and the second structure SB2 can be specified by observing the structure of the cut surface of the bump electrode 31 is not limited to the seventh embodiment, and it similarly applies to the first to sixth embodiments described above. That is, in a case where the metal bonding portion 120 is formed by metal-bonding the connection wiring 114 and the bump electrode 31, although not illustrated, it is conceivable that the outer end portion 34 of the bump electrode 31 has a shape slightly warped obliquely upward, unlike the seventh embodiment. Therefore, it is considered that it can be confirmed that the first structure is the external electrode 30 and the second structure is the connection wiring 114 in the first to sixth embodiments on the basis of the structure of the cut surface of the bump electrode 31.

In the description of the ultrasonic bonding in the above-described seventh embodiment, the metal bonding portion 120 is formed by applying the ultrasonic bonding in a state where the flexible printed circuit 110 is positioned on the upper side of the display panel 100. However, the metal bonding portion 120 may be formed by applying the ultrasonic bonding in a state where the display panel 100 is positioned on the upper side of the flexible printed circuit 110 (a state in which the connection wiring 114 of the flexible printed circuit 110 faces upward and the external electrode 30 of the display panel 100 faces downward).

### Sealing Structure

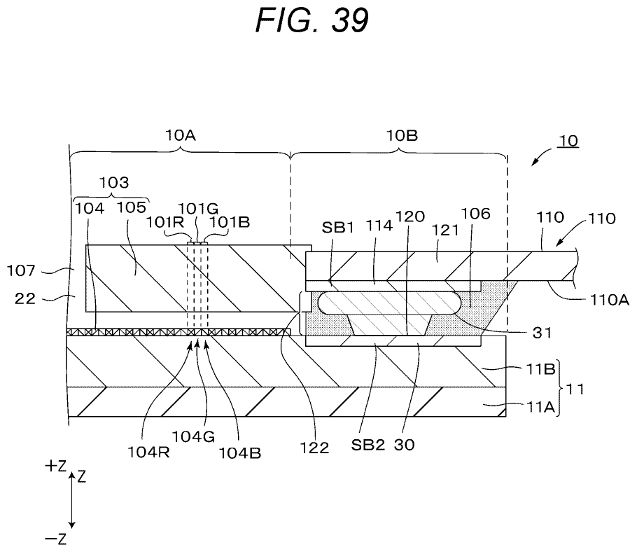

In the seventh embodiment, as illustrated in FIG. 39, the gap 122 between the flexible printed circuit 110 and the display panel 100 is preferably filled with an underfill material as a resin so as to cover the metal bonding portion 120 as described in the first embodiment. In FIG. 39, a portion covering the metal bonding portion 120 and constituted by an underfill material forms a sealing structure 106. FIG. 39 illustrates an example of a case where the sealing structure 106 is formed so as to cover the metal bonding portion 120 in the display apparatus 10 according to the seventh embodiment.

In a case where the sealing structure 106 is formed in the display apparatus 10 according to the seventh embodiment, as illustrated in Modification 2 of the first embodiment, a sealing auxiliary layer may be formed so as to cover an outer surface of a portion constituted by an underfill material (an outer peripheral surface of the sealing structure 106) (not illustrated).

### 7-2 Operation and Effects

According to the display apparatus 10 according to the seventh embodiment, effects similar to those of the first embodiment can be obtained.

At the time of manufacturing the display apparatus 10 according to the seventh embodiment, similarly to the first to sixth embodiments, there is a possibility that heat is applied to the bump electrode 31 and the surroundings thereof by a process of forming the bump electrode 31 on the surface of the first structure SB1 (referred to as a first process) and a process of metal-bonding the bump electrode 31 to the surface of the second structure SB2 (referred to as a second process). In the first process, the bump electrode 31 and the first structure SB1 may receive heat. In the second process, both the bump electrode 31, the first structure SB1, and the second structure SB2 may receive heat.

In a case where the bump electrode 31 and the first structure SB1 are constituted by different kinds of metals, it is preferable to take a measure for suppressing excessive formation of an alloy of different kinds of metals due to application of heat to a contact portion between the bump electrode 31 and the first structure SB1 a plurality of times. As such a countermeasure, for example, it is preferable to perform temperature management (management to maintain a temperature as low as possible) in the second process. In this case, the influence of heat on the contact portion between the bump electrode 31 and the first structure SB1 in the second process is reduced. Since the alloy formation at the contact portion between the bump electrode 31 and the first structure SB1 is suppressed, the bonding force between the bump electrode 31 and the first structure SB1 can be maintained, so that a display apparatus with further improved reliability can be obtained.

In addition, in a case where the first structure SB1 and the bump electrode 31 are constituted by the same type of metal, it is possible to eliminate the possibility that an alloy is formed at a contact portion between the bump electrode 31 and the first structure SB1. Therefore, even if measures such as temperature management in the second process exemplified above are omitted, it is possible to maintain a strong bonding force between the bump electrode 31 and the first structure SB1.

In the display apparatus 10 according to the seventh embodiment, the first structure SB1 is the connection wiring 114, and heat may be applied a plurality of times to the contact portion between the bump electrode 31 and the connection wiring 114 at the time of manufacturing the display apparatus 10. In the display apparatus 10 according to the seventh embodiment, in a case where the connection wiring 114 as the first structure SB1 and the bump electrode 31 are constituted by the same type of metal such as gold, for example, even if heat is applied to the first structure SB1 a plurality of times or even if measures such as temperature management in the second process are omitted, stronger bonding force can be maintained, and reliability can be further improved.

In addition, in the display apparatus 10 according to the seventh embodiment, the external electrode 30 of the display panel 100 is the second structure SB2. Therefore, in the first process, a state in which heat is not applied to the display panel 100 can be formed. Therefore, in the display apparatus 10 according to the seventh embodiment, it is possible to suppress the necessity of applying the low-temperature process for suppressing the influence of heat on the light emitting element 104 provided in the display panel 100.

### 7-3 Modification

In the display apparatus 10 according to the seventh embodiment, the metal bonding portion 120 is not limited to the case of being formed by applying ultrasonic bonding. For example, the metal bonding portion 120 may be formed by applying a welding technique. That is, the metal bonding portion 120 may be formed by bonding the second structure SB2 and the bump electrode 31 by applying heat or pressure or both heat and pressure to at least one of the second structure SB2 or the bump electrode 31. Note that it similarly applies to the first to sixth embodiments described above in that the metal bonding portion 120 may be formed by applying a welding technique.

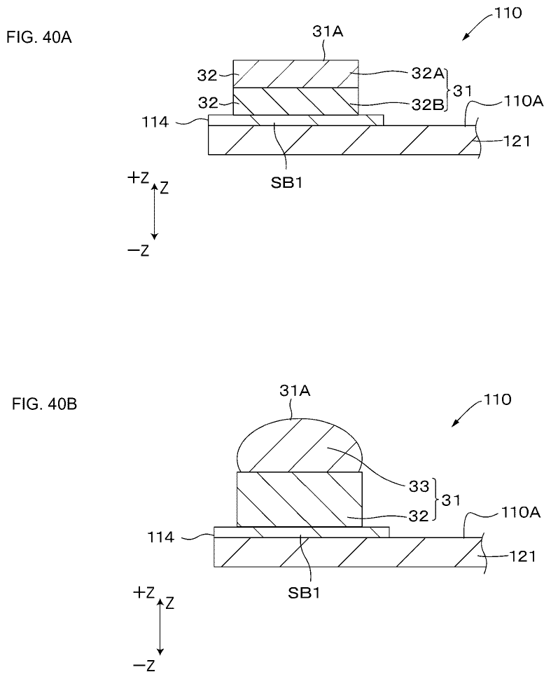

In the display apparatus 10 according to the seventh embodiment, the configuration of the bump electrode 31 is not limited to the example as illustrated in FIG. 34, and may have a structure similar to the bump electrode 31 described in the second to third embodiments in addition to Modification 1 of the first embodiment. For example, although not illustrated, the bump electrode 31 may be a bump formed by a plating method similarly to the bump electrode described in Modification 1 of the first embodiment. Further, as illustrated in FIG. 40A and FIG. 40B, in the seventh embodiment, the bump electrode 31 may have a structure in which the metal layer 32 is laminated, or may have the solder layer 33, similarly to the bump electrode 31 described in the second to third embodiments. In addition, as described in the first embodiment, also in the seventh embodiment, the bump electrode 31 may be formed by using a vapor deposition film forming method or may be formed by using a sputtering film forming method. FIG. 40A is a diagram illustrating an example in a case where the bump electrode 31 formed on the connection wiring 114 has a structure in which a metal layer (first metal layer 32A and second metal layer 32B) is laminated. FIG. 40B is a diagram illustrating an example in a case where the bump electrode 31 formed on the connection wiring 114 has a structure in which the metal layer 32 and the solder layer 33 are laminated.

The display apparatus according to the seventh embodiment may have a configuration obtained by combining the configuration described in any one of the fourth embodiment to the sixth embodiment (each configuration such as a bank structure and a groove) and the configuration described in any two or more of the first embodiment to the sixth embodiment.

### 8 Application Example

### Electronic Device

The display apparatus 10 which is an example of the display according to the present disclosure may be provided in various electronic devices. An electronic device provided with a display is particularly required to have a high resolution such as an electronic viewfinder or a head-mounted display of a video camera or a single-lens reflex camera, and the display is preferably provided in a device that is enlarged and used near eyes. Providing the display in the electronic device can be realized, for example, by providing the display apparatus according to the above-described embodiments in various electronic devices. Note that the display apparatus 10 according to the above-described embodiments includes any of the display apparatuses illustrated in the first to seventh embodiments and the modifications, and display apparatuses obtained by combining the display apparatuses.

### Specific Example 1

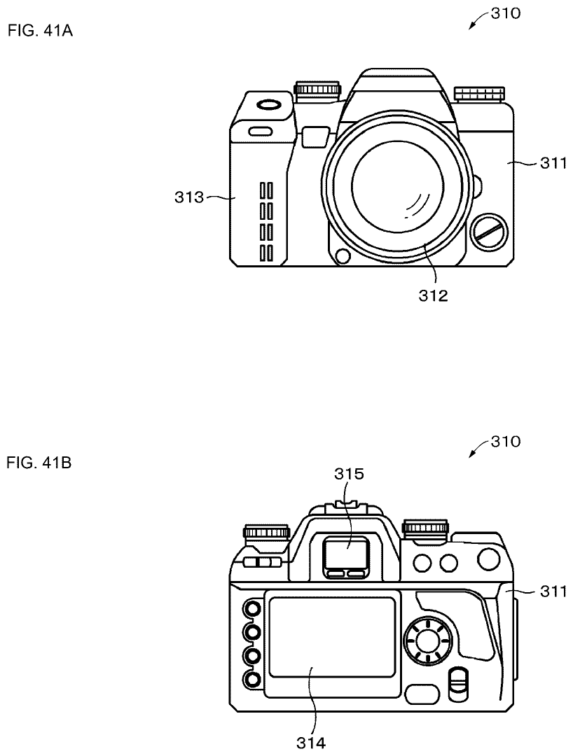

FIG. 41A is a front view illustrating an example of an external appearance of a digital still camera 310. FIG. 41B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center of the front of the camera main body portion (camera body) 311, and a grip portion 313 to be held by a person who captures an image on the front left side.

A monitor 314 is provided at a position shifted to the left from the center of the back surface of the camera main body portion 311. An electronic viewfinder (eyepiece window) 315 is provided above the monitor 314. By looking into the electronic viewfinder 315, the person who captures an image can determine the composition by visually recognizing the optical image of the subject guided from the imaging lens unit 312. As the electronic viewfinder 315, any of the display apparatuses 10 according to the above-described embodiments can be used.

### Specific Example 2

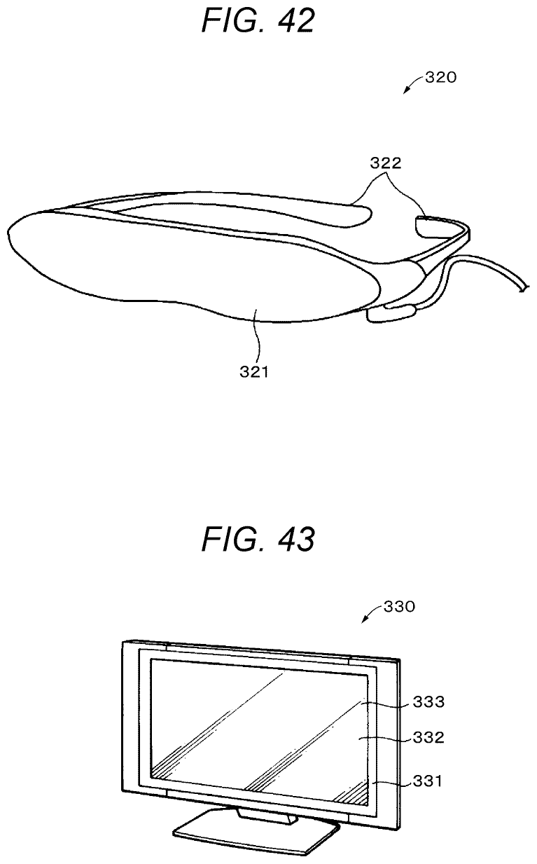

FIG. 42 is a perspective view illustrating an example of an external appearance of the head-mounted display 320. The head-mounted display 320 includes, for example, ear hooking portions 322 to be worn on the head of the user on both sides of the glass-shaped display section 321. As the display section 321, any one of the display apparatuses 10 according to the above-described embodiments and modification can be used.

### Specific Example 3

FIG. 43 is a perspective view illustrating an example of an external appearance of the television apparatus 330. The television apparatus 330 includes, for example, an image display screen section 331 including a front panel 332 and a filter glass 333, and the image display screen section 331 is configured by any of the display apparatuses 10 according to the above-described embodiments and modification.

### Specific Example 4

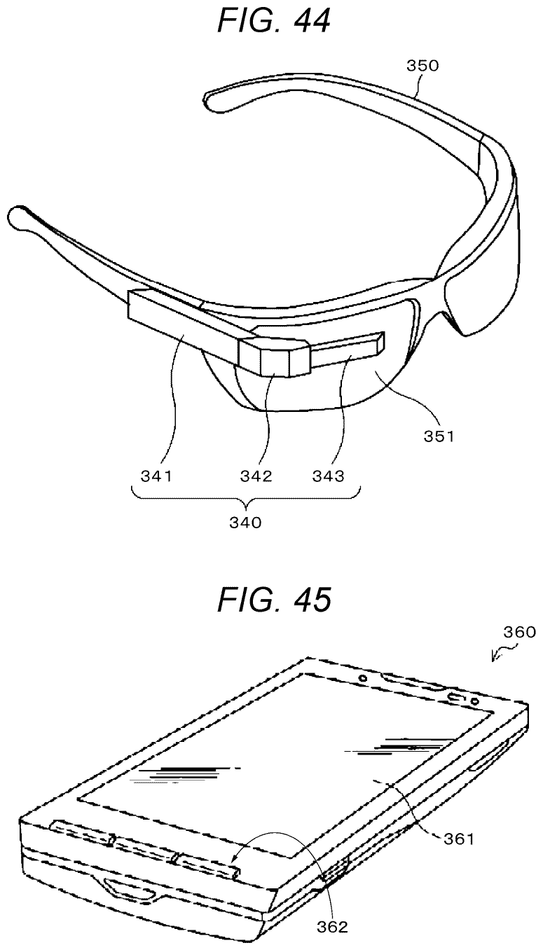

FIG. 44 illustrates an example of an appearance of the see-through head-mounted display 340. The see-through head-mounted display 340 includes a main body portion 341, an arm 342, and a lens barrel 343.

The main body portion 341 is connected to the arm 342 and the glasses 350. Specifically, an end portion of the main body portion 341 in the long side direction is coupled to the arm 342, and one side of the side surface of the main body portion 341 is coupled to the glasses 350 via a connecting member. Note that the main body portion 341 may be directly mounted on the head of the human body.

The main body portion 341 incorporates a control board for controlling the operation of the see-through head-mounted display 340 and a display section. The arm 342 connects the main body portion 341 and the lens barrel 343 and supports the lens barrel 343. Specifically, the arm 342 is coupled to the end portion of the main body portion 341 and the end portion of the lens barrel 343, and fixes the lens barrel 343. Furthermore, the arm 342 incorporates a signal line for communicating data related to an image provided from the main body portion 341 to the lens barrel 343.

The lens barrel 343 projects image light provided from the main body portion 341 via the arm 342 toward the eyes of the user wearing the see-through head-mounted display 340 through the eyepiece 351. In the see-through head-mounted display 340, the display section of the main body portion 341 includes any one of the above-described display apparatuses 10 and the like.

### Specific Example 5

FIG. 45 is a perspective view illustrating an example of an external appearance of a smartphone 360. As illustrated in FIG. 45, the smartphone 360 includes a display section 361 that displays information such as pixels, and an operation section 362 including a button or the like that receives an operation input by the user. The display apparatus 10 according to the above-described embodiments and modification can be applied to the display section 361.

### Specific Example 6

The display apparatus 10 and the like described above may be provided in a vehicle or in various displays.

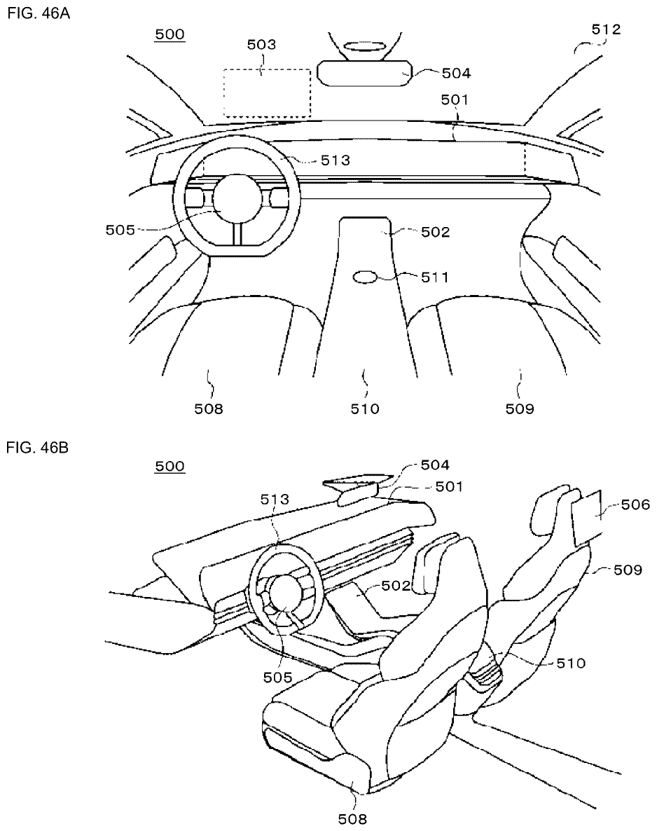

FIGS. 46A and 46B are diagrams illustrating an example of an internal configuration of a vehicle 500 provided with various displays. Specifically, FIG. 46A is a diagram illustrating an example of an internal state of the vehicle 500 from the rear to the front of the vehicle 500, and FIG. 46B is a diagram illustrating an example of an internal state of the vehicle 500 from the oblique rear to the oblique front of the vehicle 500.

The vehicle 500 includes a center display 501, a console display 502, a head-up display 503, a digital rear mirror 504, a steering wheel display 505, and a rear entertainment display 506. At least one of these displays includes any one of the above-described display apparatuses 10 and the like. For example, all of these displays may include any of the above-described display apparatuses 10 and the like.

The center display 501 is disposed on a dashboard portion facing the driver's seat 508 and the passenger seat 509. FIGS. 46A and 46B illustrate an example of the center display 501 having a horizontally long shape extending from the driver's seat 508 side to the passenger seat 509 side, but the screen size and the arrangement place of the center display 501 are arbitrary. The center display 501 can display information detected by various sensors. As a specific example, the center display 501 can display a captured image captured by the image sensor, a distance image to an obstacle in front of or on a side of the vehicle 500 measured by the ToF sensor, a passenger's body temperature detected by the infrared sensor, and the like. The center display 501 can be used to display, for example, at least one of safety-related information, operation-related information, a lifelog, health-related information, authentication/identification-related information, or entertainment-related information.

The safety-related information is information about doze sensing, looking-away sensing, sensing of mischief of a child riding together, presence or absence of wearing of a seat belt, sensing of leaving of an occupant, and the like, and is information sensed by a sensor disposed in an overlapping manner on the back surface side of the center display 501, for example. The operation-related information detects a gesture related to the operation of the occupant using the sensor. The sensed gestures may include operation of various equipment in the vehicle 500. For example, operations of air conditioning equipment, a navigation apparatus, an AV apparatus, a lighting apparatus, and the like are detected. The lifelog includes a lifelog of all the occupants. For example, the lifelog includes an action record of each occupant in the vehicle. By acquiring and storing the lifelog, it is possible to check the state of the occupant at the time of the accident. The health-related information detects the body temperature of the occupant using a sensor such as a temperature sensor, and estimates the health condition of the occupant on the basis of the detected body temperature. Alternatively, the face of the occupant may be imaged using an image sensor, and the health condition of the occupant may be estimated from the imaged facial expression. Furthermore, a conversation may be made with the occupant in an automatic voice, and the health condition of the occupant may be estimated on the basis of the answer content of the occupant. The authentication/identification-related information includes a keyless entry function of performing face authentication using a sensor, an automatic adjustment function of a sheet height and a position in face identification, and the like. The entertainment-related information includes a function of detecting operation information of the AV apparatus by the occupant using the sensor, a function of recognizing the face of the occupant by the sensor and providing content suitable for the occupant by the AV apparatus, and the like.

The console display 502 can be used to display the lifelog information, for example. The console display 502 is disposed near the shift lever 511 of the center console 510 between the driver's seat 508 and the passenger seat 509. The console display 502 can also display information detected by various sensors. In addition, the console display 502 may display an image of the periphery of the vehicle captured by the image sensor, or may display a distance image to an obstacle in the periphery of the vehicle.

The head-up display 503 is virtually displayed behind a windshield 512 in front of the driver's seat 508. The head-up display 503 can be used to display at least one of the safety-related information, the operation-related information, the lifelogs, the health-related information, the authentication/identification-related information, or the entertainment-related information, for example. Since the head-up display 503 is virtually arranged in front of the driver's seat 508 in many cases, it is suitable for displaying information directly related to the operation of the vehicle 500 such as the speed of the vehicle 500 and the remaining amount of fuel (battery).

The digital rear mirror 504 can not only display the rear of the vehicle 500 but also display the state of the occupant in the rear seat, and thus can be used to display the lifelog information, for example, by disposing the sensor to be superimposed on the back surface side of the digital rear mirror 504.

The steering wheel display 505 is disposed near the center of the steering wheel 513 of the vehicle 500. The steering wheel display 505 can be used to display at least one of the safety-related information, the operation-related information, the lifelogs, the health-related information, the authentication/identification-related information, or the entertainment-related information, for example. In particular, since the steering wheel display 505 is close to the driver's hand, it is suitable for displaying lifelog information such as the body temperature of the driver, or for displaying information regarding the operation of an AV apparatus, an air conditioning facility, or the like.

The rear entertainment display 506 is attached to the back side of the driver's seat 508 and the passenger seat 509, and is for viewing by an occupant in the rear seat. The rear entertainment display 506 can be used to display, for example, at least one of the safety-related information, the operation-related information, the lifelog, the health-related information, the authentication/identification-related information, or the entertainment-related information. In particular, since the rear entertainment display 506 is in front of the occupant in the rear seat, information related to the occupant in the rear seat is displayed. For example, information regarding the operation of the AV apparatus or the air conditioning facility may be displayed, or a result of measuring the body temperature or the like of the occupant in the rear seat by the temperature sensor may be displayed.

A sensor may be disposed on the back surface side of the display apparatus 10 or the like, and a distance to an object existing in the surroundings may be measured. Optical distance measurement methods are roughly classified into a passive type and an active type. The passive type measures a distance by receiving light from an object without projecting light from a sensor to the object. The passive type includes a lens focus method, a stereo method, a monocular vision method, and the like. In the active type, light is projected onto an object, and reflected light from the object is received by a sensor to measure a distance. Examples of the active type include an optical radar method, an active stereo method, an illuminance difference stereo method, a moire topography method, and an interference method. The display apparatus 10 and the like described above can be applied to any of these types of distance measurement. By using a sensor disposed to overlap the back surface side of the display apparatus 10 or the like described above, the above-described passive type or active type distance measurement can be performed.

Although the display apparatuses and the application examples according to the first to seventh embodiments and the modifications of the present disclosure have been specifically described above, the present disclosure is not limited to the display apparatuses and the application examples according to the first to seventh embodiments and the modifications described above, and various modifications based on the technical idea of the present disclosure are possible.

For example, the configurations, methods, steps, shapes, materials, numerical values, and the like described in the display apparatuses according to the first to seventh embodiments and the modifications described above and the application examples are merely examples, and configurations, methods, steps, shapes, materials, numerical values, and the like different from those described above may be used as necessary.

The configurations, methods, steps, shapes, materials, numerical values, and the like of the display apparatuses and application examples according to the first to seventh embodiments and modifications described above can be combined with each other without departing from the gist of the present disclosure.

The materials exemplified in the display apparatuses and the application examples according to the first to seventh embodiments and the modifications described above can be used alone or in combination of two or more unless otherwise specified.

Further, the present disclosure can adopt the following configurations.
(1)

A display including:
a display panel having a display region in which a light emitting element is disposed and an outer region formed outside the display region; and
a flexible printed circuit having connection wiring electrically connected to the display panel, in which
the display panel includes an external electrode provided in the outer region and electrically connectable to an outside,
a bump electrode is provided on the first structure in a case where one of the external electrode and the connection wiring is a first structure and the other of the external electrode and the connection wiring with respect to the first structure is a second structure, and
the bump electrode is metal-bonded to the second structure.
(2)

The display according to (1), in which
the first structure is the external electrode of the display panel, and
the second structure is the connection wiring of the flexible printed circuit.
(3)

The display according to (1), in which
the first structure is the connection wiring of the flexible printed circuit, and
the second structure is the external electrode of the display panel.
(4)

The display according to any one of (1) to (3), in which
the light emitting element is an organic electroluminescent element.
(5)

The display according to any one of (1) to (4), further including
a substrate and a covering structure provided on an upper side of the substrate and covering the light emitting element, in which
the external electrode is provided on an upper side of the substrate, and
a position of an upper surface of the covering structure is located above an upper surface of the external electrode.
(6)

The display according to any one of (1) to (5), in which
the bump electrode is constituted by any one selected from a group consisting of gold, copper, silver, and aluminum.
(7)

The display according to any one of (1) to (6), in which
the bump electrode is formed by plating.
(8)

The display according to any one of (1) to (6), in which
the bump electrode is a stud bump.
(9)

The display according to any one of (1) to (5), in which
the bump electrode is a laminate in which a plurality of metal layers constituted by different metals is laminated, and
the metal layer forming an outermost surface of the laminate is constituted by any one selected from a group consisting of gold, copper, and silver.
(10)

The display according to (9), in which
the laminate is formed by plating.
(11)

The display according to any one of (1) to (10), in which
bonding between the bump electrode and the connection wiring of the flexible printed circuit is formed by ultrasonic bonding.
(12)

The display according to any one of (1) to (5), in which
the bump electrode is a laminate in which a plurality of metal layers constituted by different metals is laminated, and
the metal layer forming an outermost surface of the laminate is constituted by solder.
(13)

The display according to (12), in which
the solder includes at least one selected from a group consisting of indium and bismuth.
(14)

The display according to (12) or (13), in which
bonding between the bump electrode and the connection wiring of the flexible printed circuit is formed by pressurization and heating.
(15)

The display according to any one of (1) to (14), further including
a substrate and a covering structure provided on an upper side of the substrate and covering the light emitting element, in which
a position of a bonding surface with the external electrode among surfaces of the flexible printed circuit is located below a position of an upper surface of the covering structure.
(16)

The display according to any one of (1) to (15), in which
a resin is filled between the flexible printed circuit and the external electrode.
(17)

The display according to (16), further including
a substrate and a covering structure provided on an upper side of the substrate and covering the light emitting element, in which
the covering structure includes at least a surface layer that forms an outermost surface of the covering structure and a protective layer that is disposed at a position closer to the light emitting element than the surface layer and contains an inorganic compound,
a bank structure is formed between the display region and the external electrode, and
the bank structure includes at least a part of the protective layer.
(18)

The display according to (17), in which
the covering structure further includes an organic functional layer containing an organic compound at least between the surface layer and the protective layer, and
the bank structure has a structure in which at least a part of the protective layer and at least a part of the organic functional layer are laminated.
(19)

The display according to (17) or (18), in which
a groove is formed between the display region and the external electrode.
(20)

The display according to (19), in which
the groove is formed in a linear shape extending along an outer edge of the display region.
(21)

The display according to (19), in which
the groove has a first portion formed linearly along an outer edge of the display region and a second portion extending outward from an end portion of the first portion.
(22)

The display according to (19), in which
the groove is provided at a plurality of locations.
(23)

The display according to (19), in which
a plurality of protruding structures protruding upward is formed on a bottom surface of the groove.
(24)

The display according to any one of (1) to (23), in which
in the display region, a counter substrate or an overcoat layer constituted by a resin material or an inorganic material is provided on an outermost surface of the display panel.
(25)

The display according to any one of (1) to (24), in which
a circuit structure different from the flexible printed circuit is electrically connected to the display panel between the display region and the external electrode.
(26)

An electronic device including
the display according to any one of (1) to (25).

### REFERENCE SIGNS LIST

10 Display apparatus
10A Display region
10B Outer region
11 Drive substrate
11A Substrate
11B Inorganic insulating layer
16 Protective layer
18 Color filter
19 Filling resin layer
20 Sealing layer
21 Planarization layer
22 Counter substrate
23 Overcoat layer
30 External electrode
31 Bump electrode
31A Outermost surface
32 Metal layer
32A First metal layer
32B Second metal layer
33 Solder layer
40 Circuit
100 Display panel
100A Outer end
103 Display structure
104 Light emitting element
104B Light emitting element
104G Light emitting element
104R Light emitting element
105 Covering structure
106 Sealing structure
107 Surface layer
110 Flexible printed circuit
110A Lower surface
114 Connection wiring
120 Metal bonding portion
121 Circuit forming body
122 Gap
123 Sealing auxiliary layer
130 Bank structure
140 Groove
150 Head
200 Circuit structure
216 Electrode pad
230 Anisotropic conductive film
230A Conductive particle
310 Digital still camera
320 Head-mounted display
330 Television apparatus
340 See-through head-mounted display
350 Glasses
360 Smartphone
500 Vehicle
D Display surface
PN Upper surface position

1. A display comprising:
a display panel having a display region in which a light emitting element is disposed and an outer region formed outside the display region; and
a flexible printed circuit having connection wiring electrically connected to the display panel, wherein
the display panel includes an external electrode provided in the outer region and electrically connectable to an outside,
a bump electrode is provided on the first structure in a case where one of the external electrode and the connection wiring is a first structure and the other of the external electrode and the connection wiring with respect to the first structure is a second structure, and
the bump electrode is metal-bonded to the second structure.

2. The display according to claim 1, wherein
the first structure is the external electrode of the display panel, and
the second structure is the connection wiring of the flexible printed circuit.

3. The display according to claim 1, wherein
the first structure is the connection wiring of the flexible printed circuit, and
the second structure is the external electrode of the display panel.

4. The display according to claim 1, wherein
the light emitting element is an organic electroluminescent element.

5. The display according to claim 1, further comprising
a substrate and a covering structure provided on an upper side of the substrate and covering the light emitting element, wherein
the external electrode is provided on an upper side of the substrate, and
a position of an upper surface of the covering structure is located above an upper surface of the external electrode.

6. The display according to claim 1, wherein
the bump electrode is constituted by any one selected from a group consisting of gold, copper, silver, and aluminum.

7. The display according to claim 1, wherein
the bump electrode is formed by plating.

8. The display according to claim 1, wherein
the bump electrode is a stud bump.

9. The display according to claim 1, wherein
the bump electrode is a laminate in which a plurality of metal layers constituted by different metals is laminated, and
the metal layer forming an outermost surface of the laminate is constituted by any one selected from a group consisting of gold, copper, and silver.

10. The display according to claim 9, wherein
the laminate is formed by plating.

11. The display according to claim 1, wherein
the bump electrode is bonded to the second structure by ultrasonic bonding.

12. The display according to claim 1, wherein
the bump electrode is a laminate in which a plurality of metal layers constituted by different metals is laminated, and
the metal layer forming an outermost surface of the laminate is constituted by solder.

13. The display according to claim 12, wherein
the solder includes at least one selected from a group consisting of indium and bismuth.

14. The display according to claim 1, wherein
the bump electrode is bonded to the second structure by pressurization and heating.

15. The display according to claim 1, further comprising
a substrate and a covering structure provided on an upper side of the substrate and covering the light emitting element, wherein
a position of a bonding surface with the external electrode among surfaces of the flexible printed circuit is located below a position of an upper surface of the covering structure.

16. The display according to claim 1, wherein
a resin is filled between the flexible printed circuit and the external electrode.

17. The display according to claim 16, further comprising
a substrate and a covering structure provided on an upper side of the substrate and covering the light emitting element, wherein
the covering structure includes at least a surface layer that forms an outermost surface of the covering structure and a protective layer that is disposed at a position closer to the light emitting element than the surface layer and contains an inorganic compound,
a bank structure is formed between the display region and the external electrode, and
the bank structure includes at least a part of the protective layer.

18. The display according to claim 17, wherein
the covering structure further includes an organic functional layer containing an organic compound at least between the surface layer and the protective layer, and
the bank structure has a structure in which at least a part of the protective layer and at least a part of the organic functional layer are laminated.

19. The display according to claim 1, wherein
a groove is formed between the display region and the external electrode.

20. The display according to claim 1, wherein
in the display region, a counter substrate or an overcoat layer constituted by a resin material or an inorganic material is provided on an outermost surface of the display panel.

21. The display according to claim 1, wherein
a circuit structure different from the flexible printed circuit is electrically connected to the display panel between the display region and the external electrode.

22. An electronic device comprising
the display according to claim 1.
